(19) United States
(12) Patent Application Publication
(10) Pub. No.: US 2025/0203910 A1
(43) Pub. Date: Jun. 19, 2025

(54) SEMICONDUCTOR DEVICE AND MANUFACTURING METHOD THEREOF

(71) Applicant: INNOSCIENCE (SUZHOU) SEMICONDUCTOR CO., LTD., Suzhou (CN)

(72) Inventor: Ronghui Hao, Suzhou (CN)

(21) Appl. No.: 18/701,988

(22) PCT Filed: Oct. 13, 2023
(86) PCT No.: PCT/CN2023/124601

§ 371 Date: Apr. 17, 2024

(51) Int. Cl. H10D 30/47; H10D 30/01; H10D 62/10; H10D 62/85; H10D 64/27

(52) U.S. Cl. CPC H10D 30/475; H10D 30/015; H10D 62/125; H10D 64/513; H10D 62/8503

(57) ABSTRACT

Some embodiments of the disclosure provide a semiconductor device. The semiconductor device comprises: a substrate; a first nitride semiconductor layer on the substrate; a second nitride semiconductor layer on the first nitride semiconductor layer and having a band gap greater than a band gap of the first nitride semiconductor layer; a group III-V dielectric layer disposed on the second nitride semiconductor layer; an electrode disposed on the second nitride semiconductor layer; and a first passivation layer disposed on the group III-V dielectric layer, wherein the group III-V dielectric layer is separated from the gate electrode by the first passivation layer.

### CROSS-REFERENCE TO RELATED APPLICATION

This application is a Section 371 National Stage Application of International Application No. PCT/CN2023/124601, filed on Oct. 13, 2023, entitled “SEMICONDUCTOR DEVICE AND MANUFACTURING METHOD THEREOF”, the whole disclosure of which is incorporated herein by reference in its entirety.

### TECHNICAL FIELD

The disclosure is related to a semiconductor device, and in particular, to a semiconductor device including a high-electron-mobility transistor (HEMT).

### DESCRIPTION OF THE RELATED ART

A semiconductor component including a direct band gap, for example, a semiconductor component including a group III-V material or group III-V compounds, may operate or work under a variety of conditions or environments (for example, different voltages or frequencies) due to its characteristics.

The foregoing semiconductor component may include a HEMT, a heterojunction bipolar transistor (HBT), a heterojunction field effect transistor (HFET), or a modulation-doped field effect transistor (MODFET).

### SUMMARY

In accordance with one aspect of the present disclosure, a semiconductor device is provided. The semiconductor device, comprising: a substrate; a first nitride semiconductor layer on the substrate; a second nitride semiconductor layer on the first nitride semiconductor layer, the second nitride semiconductor layer comprising a first surface at a first height, a second surface at a second height, a third surface at a third height and between the first surface and the second surface, and a first side connecting the second surface and third surface and extending along a direction substantially parallel to the surface of the substrate; a third nitride semiconductor layer on the third surface of the second nitride semiconductor layer; and a dielectric layer contacting the third nitride semiconductor layer and the first side of the second nitride semiconductor layer.

In accordance with one aspect of the present disclosure, a semiconductor device is provided. The semiconductor device, comprising: a substrate; a first nitride semiconductor layer on the substrate; a second nitride semiconductor layer having a first surface at a first height, a second surface at a second height, a third surface at a third height and between the first surface and second surface, and a first side connecting the second surface and the second surface, wherein the first side extends along a direction substantially parallel to the surface of the substrate, a third nitride semiconductor layer having a fourth surface at the third height, a fifth surface at the fourth height, and a second side connecting the fourth surface and fifth surface, wherein the second side comprises a portion substantially perpendicular to the surface of the substrate.

In accordance with one aspect of the present disclosure, a method for fabricating a semiconductor device is provided. The method for fabricating a semiconductor device, comprising: providing a substrate; forming a first nitride semiconductor layer on the substrate; forming a second nitride semiconductor layer on the first nitride semiconductor layer, wherein the second nitride semiconductor layer comprises a first surface at a first height and a second surface at a second height; etching the second surface of the second nitride semiconductor layer to form a third surface at a third height and between the first surface and the second surface, and a first side connecting the second surface and third surface, wherein the first side extends along a direction substantially parallel to the surface of the substrate; forming a dielectric layer on the second nitride semiconductor layer; etching the dielectric layer thereby exposing a portion of the third surface of the second nitride semiconductor layer; and forming a third nitride semiconductor layer on the third surface of the second nitride semiconductor layer, wherein the dielectric layer contacts the third nitride semiconductor layer and the first side of the second nitride semiconductor layer.

The semiconductor device and the method of according to the present disclosure prevent the growth of the third nitride semiconductor layer on the sidewall of a recess as well as a direct contact between the third nitride semiconductor layer and the sidewall, such as the first side of the second surface described above, in the growth of the third nitride semiconductor layer. By having a first dielectric layer, lateral growth is inhibited, contamination on the epitaxial surface is reduced, and therefore the properties of the growth are improved.

It is another object of the present disclosure to improve the manufacture of semiconductor components. By forming a dielectric layer in the growth process, the second nitride semiconductor layer and the third nitride semiconductor layer may have various structures for characteristics or functions on demand, and the relative configuration among components, such as the source electrode, gate electrode, and drain electrode, can be easily modified.

### BRIEF DESCRIPTION OF THE DRAWINGS

Aspects of the disclosure will become more comprehensible from the following detailed description made with reference to the accompanying drawings. It should be noted that, various features may not be drawn to scale. In fact, the sizes of the various features may be increased or reduced arbitrarily for the purpose of clear description.

FIG. 1A depicts a semiconductor device according to some embodiments of the disclosure.

FIG. 1B shows a cathodoluminescence (CL) image of the dotted box in FIG. 1A;

FIG. 2A is a side view of a semiconductor device according to some embodiments of the disclosure;

FIG. 2B is another side view of a semiconductor device according to some embodiments of the disclosure;

FIG. 3A-3H illustrate various stages of a method for manufacturing the semiconductor device of FIG. 2A;

FIG. 4 is a side view of a semiconductor device according to some embodiments of the disclosure;

FIG. 5A-5F illustrate various stages of a method for manufacturing the semiconductor device of FIG. 4;

FIG. 6 is a side view of a semiconductor device according to some embodiments of the disclosure;

FIG. 7A-7C illustrate various stages of a method for manufacturing the semiconductor device of FIG. 6;

FIG. 8A-8D each illustrate a semiconductor device according to some embodiments of the disclosure;

FIG. 9A-9C each illustrate a semiconductor device according to some embodiments of the disclosure; and

FIG. 10 shows a schematic diagram illustrating the distribution of the dopants in a nitride semiconductor layer according to the present disclosure.

Common reference numerals are used throughout the drawings and the detailed description to indicate the same or similar components. The present disclosure will be more apparent from the following detailed description taken in conjunction with the accompanying drawings.

### DETAILED DESCRIPTION

The following disclosure provides many different embodiments or examples for implementing different features of the provided subject matter. Specific examples of components and arrangements are described below. Certainly, these descriptions are merely examples and are not intended to be limiting. In the disclosure, in the following descriptions, the description of the first feature being formed on or above the second feature may include an embodiment in which the first feature and the second feature are formed to be in direct contact, and may further include an embodiment in which an additional feature may be formed between the first feature and the second feature to enable the first feature and the second feature to be not in direct contact. In addition, in the disclosure, reference numerals and/or letters may be repeated in examples. This repetition is for the purpose of simplification and clarity, and does not indicate a relationship between the described various embodiments and/or configurations.

The embodiments of the disclosure are described in detail below. However, it should be understood that many applicable concepts provided by the disclosure may be implemented in a plurality of specific environments. The described specific embodiments are only illustrative and do not limit the scope of the disclosure.

A direct band gap material, such as a group III-V compound, may include but is not limited to, for example, gallium arsenide (GaAs), indium phosphide (InP), gallium nitride (GaN), Indium gallium arsenide (InGaAs), Indium aluminum arsenide (InAlAs), and the like.

As used herein, x direction is defined as the direction extending from the source electrode to the drain electrode of a semiconductor device and substantially parallel to the surface of the substrate of the semiconductor device, and z direction is defined as the direction substantially perpendicular to the x direction. z direction is defined as the direction substantially perpendicular to the surface of the semiconductor device.

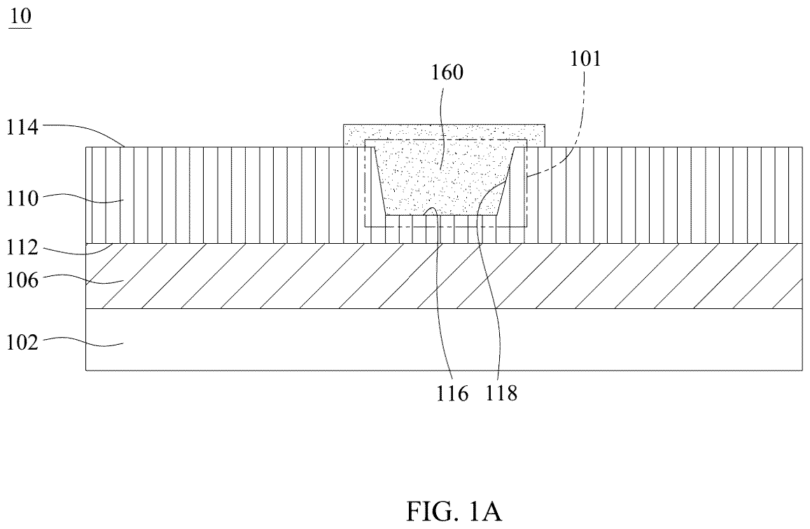

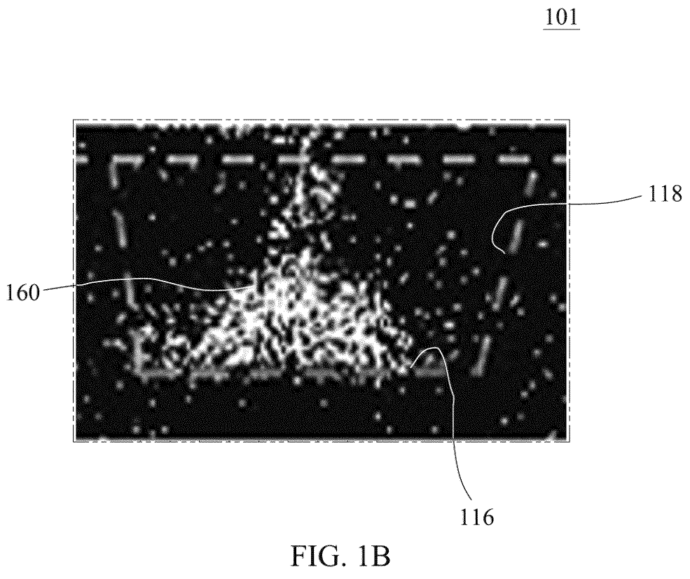

FIG. 1A is a side view of a semiconductor device 10 according to some embodiments of the disclosure. The semiconductor device, comprises a substrate 102; a nitride semiconductor layer 106 on the substrate 102; a nitride semiconductor layer 110 on the nitride semiconductor layer 106, the nitride semiconductor layer 110 comprising a surface 112 at a first height, a surface 114 at a second height, a surface 116 at a third height and between the surface 112 and the surface 114, and a side 118 connecting the surface 114 and surface 112 and; a nitride semiconductor layer 160 on the surface 116 of the nitride semiconductor layer 110. The side 118 may extend along the x direction. The side 118 may extend along the y direction.

Some factors may affect the properties of the growth of the nitride semiconductor layer 160 on the surface 116 of the nitride semiconductor layer 110. Being of two different materials, the lattice constant of the nitride semiconductor layer 160 may not conform to the lattice constant of the nitride semiconductor layer 110 on the epitaxial plane. For the nitride semiconductor layer 160, the lateral growth rate of is higher than the vertical growth rate. FIG. 1B is a CL image of the dotted box 101 in FIG. 1A. The brighter dots reflects the distribution of the p-type dopants, e.g. Mg. The difference in vertical and lateral growth rates of the nitride semiconductor layer 160 leads to inhomogeneous dopant distribution. The dopants are concentrated away from the side 118. The dopants are concentrated approximately to the surface 116. Accordingly, a p-i-n junction having low potential energy barrier is formed adjacent to the side 118 and causes failure in high temperature gate bias or high temperature reverse bias.

The formation of the device 10 involves selective recessing and epitaxial growth processes. It is difficult to control vertical etching and therefore recessing methods easily result the side 118 inclination. The inclined the side 118 becomes an effective site for capture of adatoms, leading to lateral growth. Therefore, the growth of the nitride semiconductor layer 160 on the nitride semiconductor layer 118 includes a lateral growth from the side 118 and vertical growth from the surface 116. Usually, there is a competition between the lateral growth and the vertical growth, which leads to anisotropic growth. Because lateral growth rate is generally higher than the vertical growth rate, unintentionally doped regions are formed in the nitride semiconductor layer 160 during the growth and are deleterious to the depletion ability of the nitride semiconductor layer 160. Moreover, the side 118 easily accumulates contaminations in metal organic chemical vapor deposition (MOCVD), which reduces the stability and controllability of the device 10.

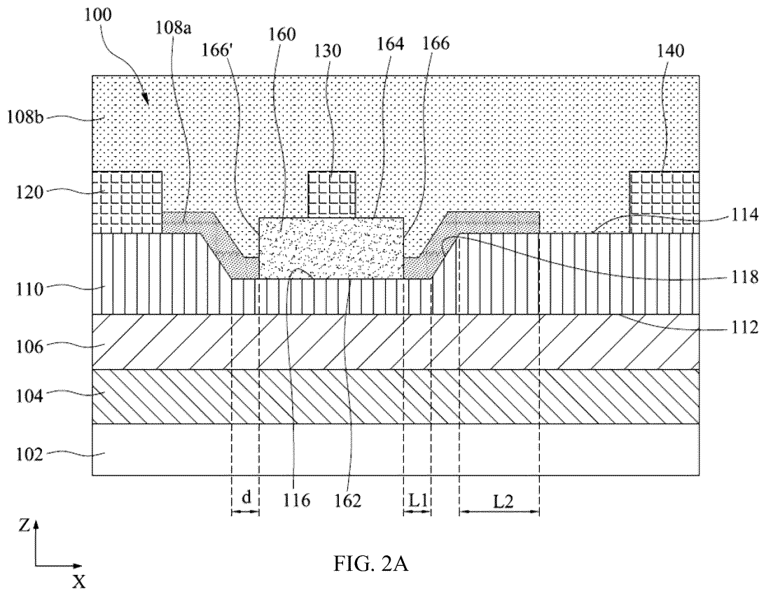

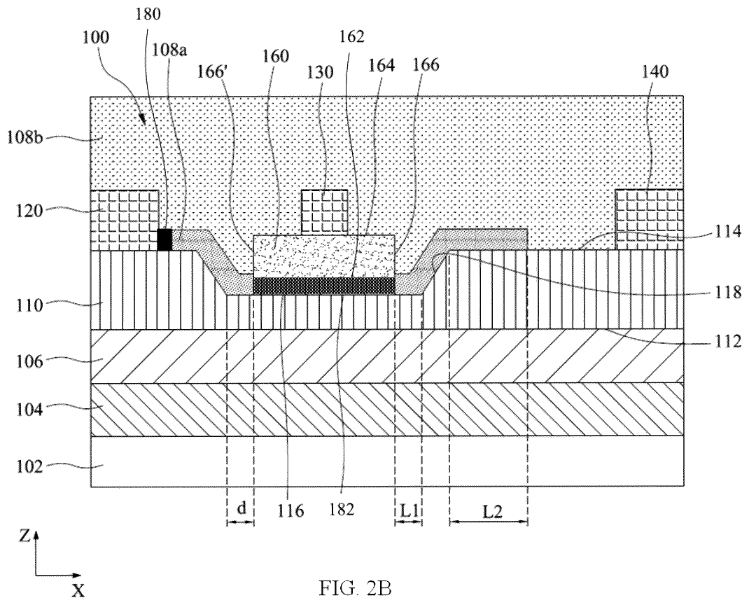

FIG. 2A is a side view of a semiconductor device 100 according to some embodiments of the disclosure.

As shown in FIG. 2A, the semiconductor device 100 may include the following essential elements: a substrate 102, a nitride semiconductor layer 106, a nitride semiconductor layer 110, a dielectric layer 108a, and a nitride semiconductor layer 160.

The device 100 may further include a buffer layer 104. The device 100 may further include an electrode 120. The electrode 120 may be a source electrode. The electrode 120 may be a drain electrode. The device 100 may further include an electrode 130. The electrode 130 may be a gate electrode. The device 100 may further include an electrode 140. The electrode 140 may be a drain electrode if the electrode 120 is a source electrode. The electrode 140 may be a source electrode if the electrode 120 is a drain electrode. The device 100 may further include a dielectric layer 108b.

The substrate 102 may include, for example, but is not limited to, silicon (Si), doped silicon (doped Si), silicon carbide (SiC), germanium silicide (SiGe), gallium arsenide (GaAs), or another semiconductor material. The substrate 102 may include an intrinsic semiconductor material. The substrate 102 may include a p-type semiconductor material. The substrate 102 may include a silicon layer doped with boron (B). The substrate 102 may include a silicon layer doped with gallium (Ga). The substrate 102 may include an n-type semiconductor material. The substrate 102 may include a silicon layer doped with arsenic (As). The substrate 102 may include a silicon layer doped with phosphorus (P).

The buffer layer 104 may be disposed on the substrate 102. The buffer layer 104 may include nitrides. The buffer layer 104 may include, for example, but is not limited to, aluminum nitride (AlN). The buffer layer 104 may include, for example, but is not limited to, aluminum gallium nitride (AlGaN). The buffer layer 104 may include a multilayer structure. The buffer layer 104 may include a superlattice layer with periodic structure of two or more materials. The buffer layer 104 may include a single layer structure.

The nitride semiconductor layer 106 may be disposed on the substrate 102. The nitride semiconductor layer 106 may be disposed on the buffer layer 104. The nitride semiconductor layer 106 may include group III-V materials. The nitride semiconductor layer 106 may be a nitride semiconductor layer. The nitride semiconductor layer 106 may include, for example, but is not limited to, group III nitride. The nitride semiconductor layer 106 may include, for example, but is not limited to, GaN. The nitride semiconductor layer 106 may include, for example, but is not limited to, AlN. The nitride semiconductor layer 106 may include, for example, but is not limited to, InN. The nitride semiconductor layer 106 may include, for example, but is not limited to, compound InₓAl_{y}Ga_{1-x-y}N, where x+y≤1. The nitride semiconductor layer 106 may include, for example, but is not limited to, compound Al_{y}Ga_{(1-y)} N, where y≤1.

The nitride semiconductor layer 110 may be disposed on the nitride semiconductor layer 106. The nitride semiconductor layer 110 may include group III-V materials. The nitride semiconductor layer 110 may be a nitride semiconductor layer. The nitride semiconductor layer 110 may include, for example, but is not limited to, group III nitride. The nitride semiconductor layer 110 may include, for example, but is not limited to, compound Al_{y}Ga_{(1-y)} N, where y≤1. The nitride semiconductor layer 110 may include, for example, but is not limited to, GaN and AlGaN. The nitride semiconductor layer 110 may include, for example, but is not limited to, AlN. The nitride semiconductor layer 110 may include, for example, but is not limited to, InN. The nitride semiconductor layer 110 may include, for example, but is not limited to, compound InₓAl_{y}Ga_{1-x-y}N, where x+y≤1.

A heterojunction may be formed between the nitride semiconductor layer 110 and the nitride semiconductor layer 106. The nitride semiconductor layer 110 may have a band gap greater than a band gap of the nitride semiconductor layer 106. For example, the nitride semiconductor layer 110 may include AlGaN that may have a band gap of about 4 eV, and the nitride semiconductor layer 106 may include GaN that may have a band gap of about 3.4 eV.

In the semiconductor device 100, the nitride semiconductor layer 106 may be used as a channel layer. In the semiconductor device 100, the nitride semiconductor layer 106 may be used as a channel layer disposed on the buffer layer 104. In the semiconductor device 100, the nitride semiconductor layer 110 may be used as a barrier layer. In the semiconductor device 100, the nitride semiconductor layer 110 may be used as a barrier layer disposed on the nitride semiconductor layer 106.

In the semiconductor device 100, because the band gap of the nitride semiconductor layer 106 is less than the band gap of the nitride semiconductor layer 110, two dimensional electron gas (2DEG) may be formed in the nitride semiconductor layer 106. In the semiconductor device 100, because the band gap of the nitride semiconductor layer 106 is less than the band gap of the nitride semiconductor layer 110, 2DEG may be formed in the nitride semiconductor layer 106 and the 2DEG is close to the interface of the nitride semiconductor layer 110 and the nitride semiconductor layer 106. In the semiconductor device 100, because the band gap of the nitride semiconductor layer 110 is greater than the band gap of the nitride semiconductor layer 106, 2DEG may be formed in the nitride semiconductor layer 106. In the semiconductor device 100, because the band gap of the nitride semiconductor layer 110 is greater than the band gap of the nitride semiconductor layer 106, 2DEG may be formed in the nitride semiconductor layer 106 and the 2DEG is close to the interface of the nitride semiconductor layer 110 and the nitride semiconductor layer 106.

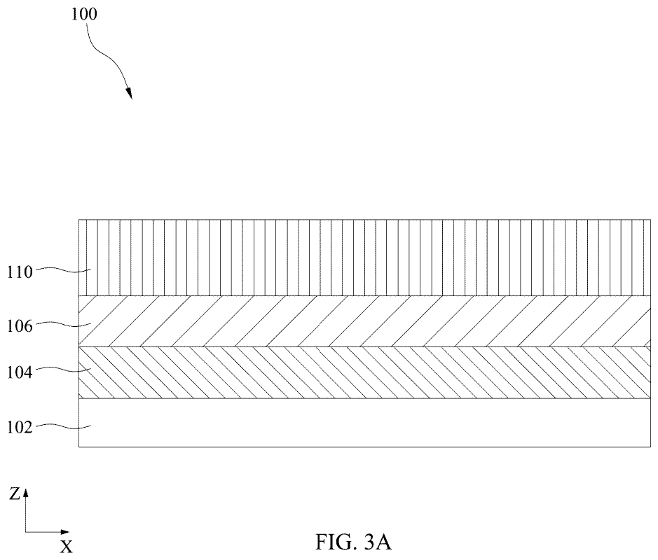

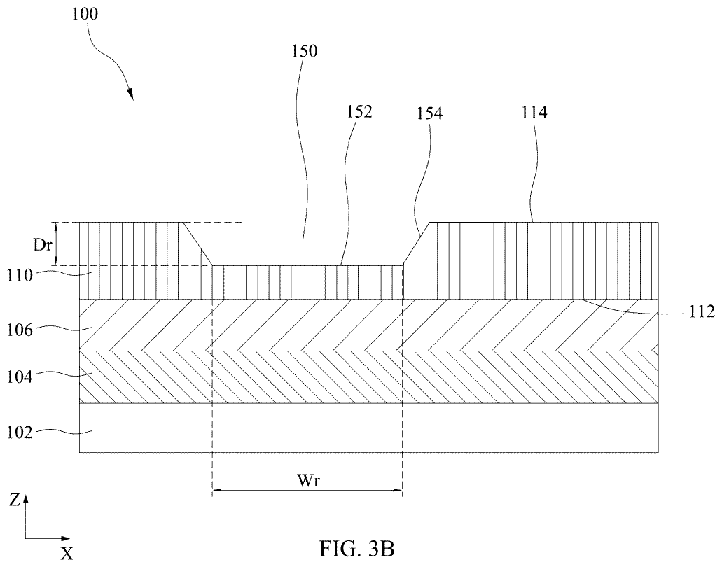

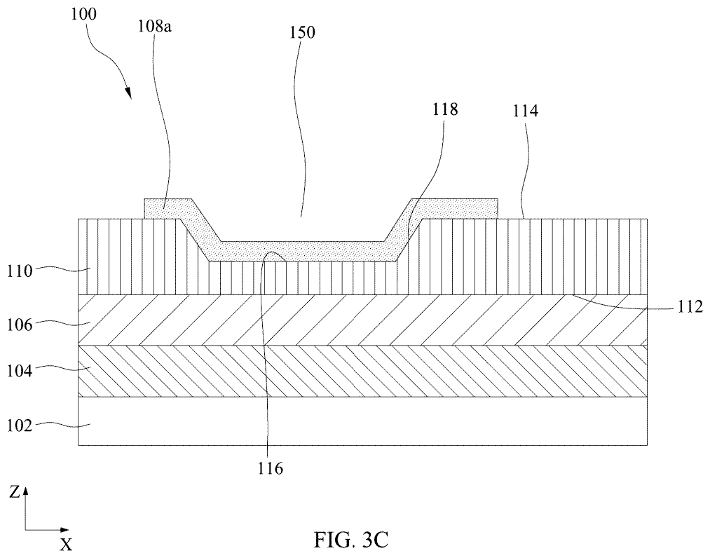

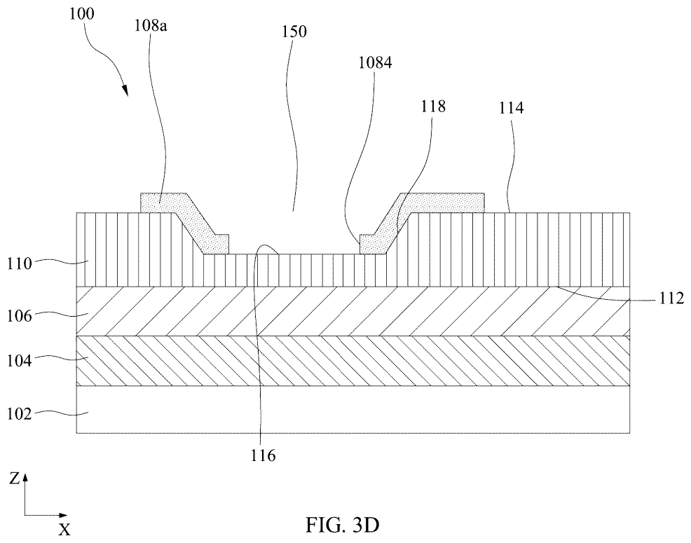

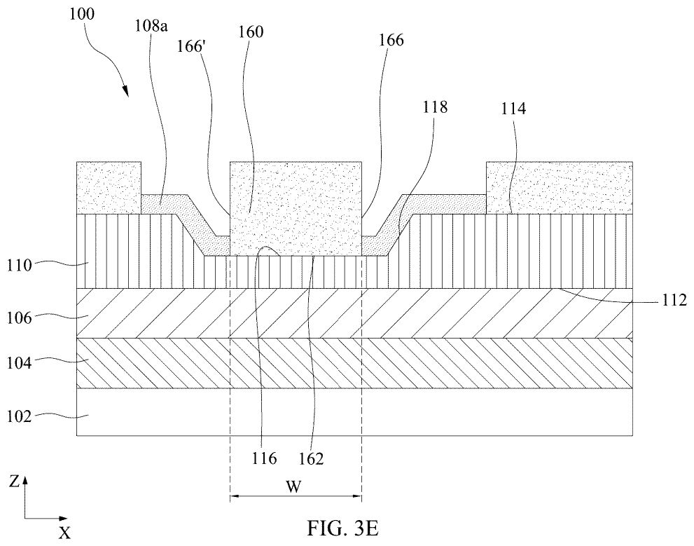

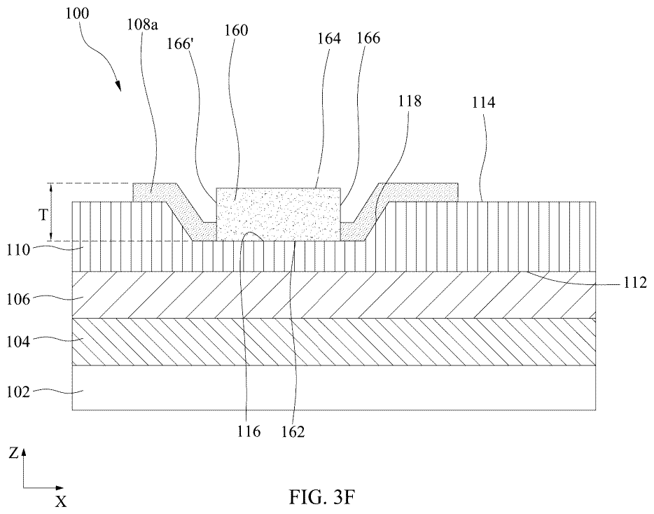

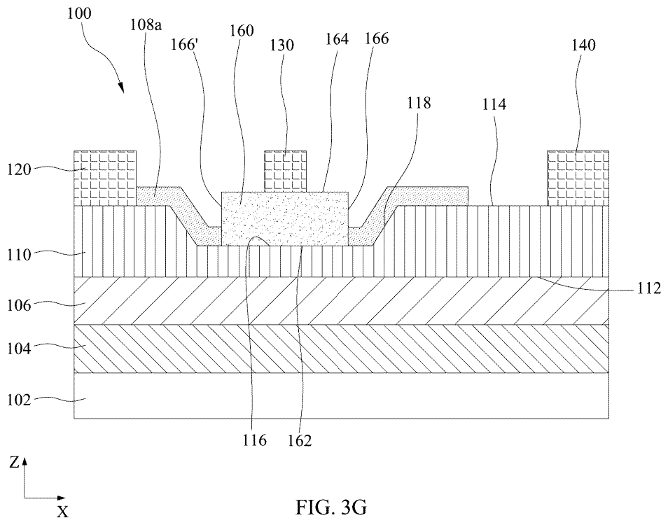

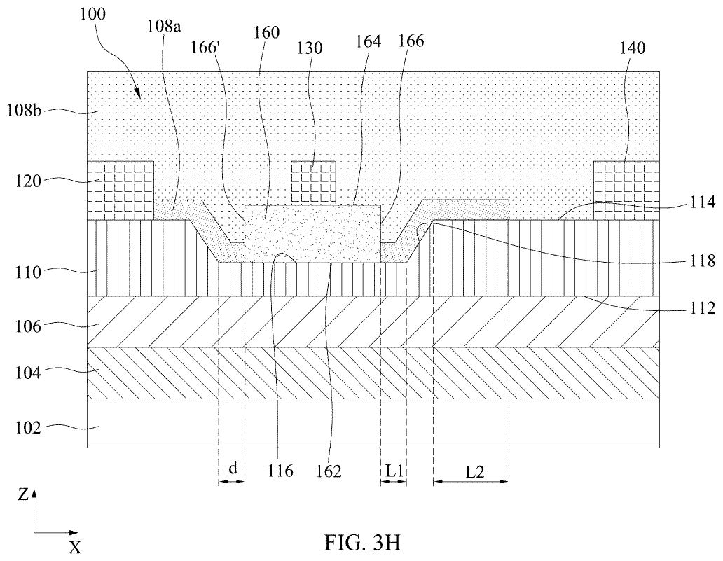

The nitride semiconductor layer 110 comprises a surface 112 facing the nitride semiconductor layer 106. The nitride semiconductor layer 110 comprises a surface 112 at a first height. The nitride semiconductor layer 110 comprises a second surface 114 opposing the surface 112. The nitride semiconductor layer 110 comprises a surface 114 at a second height. The nitride semiconductor layer 110 may further comprise a third surface 116 arranged between the surface 112 and the surface 114. The nitride semiconductor layer 110 comprises a surface 116 at a third height. In the z direction, the second height is greater than the first height. In the z direction, the third height is greater than the first height. In the z direction, the second height is greater than the third height. In the x direction, the surfaces 116 and 114 are spaced apart. The projection of the surface 116 to the substrate 102 and the projection of the surface 114 to the substrate 102 are not overlapped. The nitride semiconductor layer 110 may further comprise a side 118 connecting the surface 114 and surface 116. The side 118 extends along the x direction. The side 118 extends along the z direction. The side 118 is inclined with respect to the x direction. The side 118 is include in with respect to the z direction. The surface 114, the surface 116 and the side 118 may together form a recess 150 (as shown in FIGS. 3A-3H) on the nitride semiconductor layer 110.

The nitride semiconductor layer 160 comprises a surface 162 facing the nitride semiconductor layer 110. The nitride semiconductor layer 160 comprises the surface 162 at the third height. The nitride semiconductor layer 160 comprises a surface 164 opposing the surface 162. The nitride semiconductor layer 160 comprises the surface 164 at the fourth height. In the z direction, the fourth height is greater than the first height. In the z direction, the fourth height is greater than the second height. In the z direction, the fourth height is greater than the third height. In the z direction, the fourth height is less than the second height. The surface 162 is between the surface 112 and surface 114 of the nitride semiconductor layer 110. The surface 114 of the nitride semiconductor layer 110 is between the surface 162 and the surface 164 of the nitride semiconductor layer 160. The surface 164 of the nitride semiconductor layer 160 is between the surface 162 and the surface 114 of the nitride semiconductor layer 110. The projection of the surface 164 of the nitride semiconductor layer 160 to the substrate 102 overlaps the projection of the surface 114 of the nitride semiconductor layer 110 to the substrate 102. The projection of the surface 164 of the nitride semiconductor layer 160 to the substrate 102 overlaps the projection of the side 118 of the nitride semiconductor layer 110 to the substrate 102. The nitride semiconductor layer 160 does not contact the side 118 of the nitride semiconductor layer 110.

The nitride semiconductor layer 160 may comprise a group III-V dielectric material. The nitride semiconductor layer 160 may comprise a doped group III-V dielectric material. The nitride semiconductor layer 160 may comprise a p-type doped group III-V compound. The nitride semiconductor layer 160 and the nitride semiconductor layer 110 may have an epitaxial relationship. The exemplary materials of the p-type doped III-V compound can include, for example but are not limited to, p-doped group III-V nitride semiconductor materials, such as p-type GaN, p-type AlGaN, p-type InN, p-type AlInN, p-type InGaN, p-type AlInGaN, or combinations thereof. The p-doped materials are achieved by using a p-type impurity, such as Be, Mg, Zn, Cd, and Mg.

The nitride semiconductor layer 160 may further comprise a side 166 connecting the surface 162 and surface 164 of the nitride semiconductor layer 160. The side 166 may face the electrode 140. The side 166 may extend along the x direction. The projection of the side 166 of the nitride semiconductor layer 160 to the substrate 102 non-overlaps the projection of the surface 162 of the nitride semiconductor layer 160 to the substrate 102. The projection of the side 166 to the substrate 102 overlaps the projection of the surface 162 to the substrate 102. The projection of the side 166 of the nitride semiconductor layer 160 to the substrate 102 non-overlaps the projection of the surface 164 of the nitride semiconductor layer 160 to the substrate 102. The projection of the side 166 to the substrate 102 overlaps the projection of the surface 164 to the substrate 102.

In one embodiments, the side 166 of the nitride semiconductor layer 160 may comprise multiple portions. The side 166 of the nitride semiconductor layer 160 may comprise a portion substantially perpendicular to the surface of the substrate 102. The side 166 of the nitride semiconductor layer 160 may comprise multiple portions that are substantially perpendicular to the surface of the substrate 102. The multiple portions are not in contact with one another. The side 166 of the nitride semiconductor layer 160 may comprise a portion extending along the x direction. The side 166 of the nitride semiconductor layer 160 may comprise multiple portions that extend along the x direction. The said multiple portions may or may not be in contact with one another. The projection of the side 166 of the nitride semiconductor layer 160 to the surface of the substrate 102 does not overlap (or non-overlaps) the projection of the surface 162 of the nitride semiconductor layer 160 to the surface of the substrate 102. However, in yet another embodiment, the projection of the side 166 of the nitride semiconductor layer 160 to the surface of the substrate 102 may overlap the projection of the surface 162 of the nitride semiconductor layer 160 to the surface of substrate 102. The projection of a portion of the side 166 of the nitride semiconductor layer 160 to the surface of the substrate 102 does not overlap the projection of the surface 164 of the nitride semiconductor layer 160 to the surface of the substrate 102. However, in yet another embodiment, the projection of a portion of the side 166 of the nitride semiconductor layer 160 to the surface of the substrate 102 may overlap the projection of the surface 164 of the nitride semiconductor layer 160 to the surface of the substrate 102. The side 166 comprises a first portion substantially perpendicular to the surface of the substrate 102 and a second portion extending along the x direction. The side 166 further comprises a third portion perpendicular to the surface of the substrate 102. The second portion is between the first portion and the third portion.

The projection of the side 166 of the nitride semiconductor layer 160 to the substrate 102 does not overlap the projection of the side 118 of the nitride semiconductor layer 110 to the substrate 102. The projection of the side 166 to the substrate 102 overlaps the projection of the side 118 to the substrate 102. The projection of the side 166 of the nitride semiconductor layer 160 to the normal of the substrate 102 overlaps the projection of the side 118 of the nitride semiconductor layer 110 to the normal of the substrate 102. The projection of a portion of the side 166 of the nitride semiconductor layer 160 to the normal of the substrate 102 does not overlap the projection of the side 118 of the nitride semiconductor layer 110 to the normal of the substrate 102. The projection of the side 166 of the nitride semiconductor layer 160 to the z direction overlaps the projection of the side 118 of the nitride semiconductor layer 110 to the z direction. The projection of a portion of the side 166 of the nitride semiconductor layer 160 to the z direction does not overlap the projection of the side 118 of the nitride semiconductor layer 110 to the z direction. In the x direction, the side 166 and the side 118 comprise a distance d therebetween on the third height. The distance d may be of approximately 0 nm to approximately 500 nm, preferably between approximately 0 nm and approximately 250 nm, more preferably between approximately 10 nm and approximately 120 nm, and even more preferably between approximately 40 nm and approximately 80 nm.

The nitride semiconductor layer 160 may further comprise a side 166′ connecting the surface 162 and surface 164. The arrangement of the side 166′ is substantially the same as that of the side 166, except that the side 166′ faces the electrode 120. The side 166′ is arranged opposed to the side 166.

The dielectric layer 108a may be disposed on the nitride semiconductor layer 110. The dielectric layer 108a may be in contact with the nitride semiconductor layer 110. The dielectric layer 108a may cover the nitride semiconductor layer 110. The dielectric layer 108a may contact the side 118 of the nitride semiconductor layer 110. The dielectric layer 108a may cover the side 118 of the nitride semiconductor layer 110. The dielectric layer 108a does not contact the surface 116 of the nitride semiconductor layer 110. The dielectric layer 108a may contact the surface 116 of the nitride semiconductor layer 110. The dielectric layer 108a may separate the nitride semiconductor layer 160 from the side 118 of the nitride semiconductor layer 110. The dielectric layer 108a may be disposed between the nitride semiconductor layer 160 and the nitride semiconductor layer 110. The dielectric layer 108a may be disposed between the side 118 of the nitride semiconductor layer 110 and the side 166 of the nitride semiconductor layer 160. The dielectric layer 108a may contact the side 166 of the nitride semiconductor layer 160. The dielectric layer 108a may contact the side 166′ of the nitride semiconductor layer 160. The dielectric layer 108a may surround at least a portion of the side 166 of the nitride semiconductor layer 160. The dielectric layer 108a may surround the side 166 of the nitride semiconductor layer 160. The dielectric layer 108a may be in contact with the electrode 120. The dielectric layer 108a may be in contact with the electrode 140. The dielectric layer 108a may be between the third height and the fourth height. The dielectric layer 108a may be between the second height and the third height. The dielectric layer 108a may be between the second height and the fourth height.

The dielectric layer 108a may include a dielectric material. The dielectric layer 108a may include a non-group III-V dielectric material. The dielectric layer 108a may include nitride. The dielectric layer 108a may include, for example, but is not limited to, silicon nitride (SiN). The dielectric layer 108a may include oxide. The first dielectric layer 108a may include, for example, but is not limited to, silicon oxide (SiO₂). The dielectric layer 108a may include an electrical insulation material, for example, but is not limited to, hydrogen silsesquioxane polymers (HSQ). The dielectric layer 108a may have a thickness between approximately 10 nm and approximately 500 nm, preferably between approximately 30 nm and approximately 200 nm, more preferably between approximately 40 nm and approximately 90 nm.

The dielectric layer 108a may extend a length L1 on the surface 116 of the nitride semiconductor layer 110 along the x direction. The dielectric layer 108a may extend on the surface 114 of the nitride semiconductor layer 110. The dielectric layer 108a may extend a length L2 on the surface 114 of the nitride semiconductor layer 110 along the x direction. The length L2 is of 2% to 100% of the distance between the nitride semiconductor layer 160 and the electrode 140 (L_{gd}) along the x direction. The length L1 may be different from the length L2. The length L2 may be longer than the length L1. The length L1 may be identical to the length L2. The length L1 may range between approximately 0 nm and approximately 500 nm, preferably between approximately 0 nm and approximately 250 nm, more preferably between approximately 10 nm and approximately 120 nm, and even more preferably between approximately 40 nm and approximately 80 nm. The length L2 may range between approximately 0 nm and approximately 1000 nm, preferably between approximately 50 nm and approximately 500 nm, more preferably between approximately 70 nm and approximately 300 nm, and even more preferably between approximately 100 nm and approximately 200 nm.

The dielectric layer 108b may be disposed on the nitride semiconductor layer 110. The dielectric layer 108b may be disposed on the nitride semiconductor layer 160. The dielectric layer 108b may be disposed on the dielectric layer 108a. The dielectric layer 108b may cover the nitride semiconductor layer 160. The dielectric layer 108b may cover the dielectric layer 108a. The dielectric layer 108b may surround the nitride semiconductor layer 160. The dielectric layer 108b may be in contact with the nitride semiconductor layer 110. The dielectric layer 108b may be in contact with the nitride semiconductor layer 160. The dielectric layer 108b may be in contact with the dielectric layer 108a. The dielectric layer 108b may be in contact with the side 166 of the nitride semiconductor layer 160. The dielectric layer 108b does not contact the side 166 of the nitride semiconductor layer 160. The dielectric layer 108b may contact the side 166 of the nitride semiconductor layer 160. The dielectric layer 108b may contact the side 166′ of the nitride semiconductor layer 160. The dielectric layer 108b may be in contact with the electrode 120. The dielectric layer 108b may be in contact with the electrode 130. The dielectric layer 108b may be in contact with the electrode 140. The dielectric layer 108b may separate the electrode 130 from the electrode 120. The dielectric layer 108b may separate the electrode 130 from the electrode 140. The dielectric layer 108b may not contact the surface 116. The dielectric layer 108b may not contact the surface 114.

The dielectric layer 108b may include a dielectric material. The dielectric layer 108b may include a non-group III-V dielectric material. The dielectric layer 108b may include nitride. The dielectric layer 108b may include, for example, but is not limited to, SiN. The dielectric layer 108b may include oxide. The dielectric layer 108b may include, for example, but is not limited to, SiO₂. The dielectric layer 108b may electrically isolate the electrode 130. The dielectric layer 108b may include an electrical insulation material, for example, but is not limited to, hydrogen silsesquioxane polymers (HSQ). The dielectric layer 108b may electrically isolate the electrode 120. The dielectric layer 108b may electrically isolate the electrode 140. The dielectric layer 108b may have a thickness between approximately 10 nm and approximately 2000 nm, preferably between approximately 50 nm and approximately 1000 nm, more preferably between approximately 100 nm and approximately 500 nm.

The dielectric layer 108b may have a different material from that of the dielectric layer 108a. The dielectric layer 108b may have a material identical to that of the dielectric layer 108a. As the dielectric layer 108b and the dielectric layer 108a have the same material, the dielectric layer 108b and the dielectric layer 108a may be regarded as one single layer. For example, the dielectric layer 108a may include SiO₂ and the dielectric layer 108b may include SiN. For example, the dielectric layer 108a may include SiN and the dielectric layer 108b may include SiN. For example, the dielectric layer 108a may include SiO₂ and the dielectric layer 108b may include SiO₂. For example, the dielectric layer 108a may include SiN and the dielectric layer 108b may include SiO₂.

The electrode 120 may be disposed on the nitride semiconductor layer 110. The electrode 120 may contact the nitride semiconductor layer 110. The electrode 120 may be electrically connected to the nitride semiconductor layer 106. The electrode 120 may be electrically connected to the nitride semiconductor layer 106 through the nitride semiconductor layer 110. A portion of the electrode 120 may be surrounded by the nitride semiconductor layer 110. A portion of the electrode 120 may be surrounded by the dielectric layer 108a. A portion of the electrode 120 may be surrounded by the dielectric layer 108b. The electrode 120 may include a conductive material. The electrode 120 may include a metal. The electrode 120 may include, for example, but is not limited to, Al. The electrode 120 may include, for example, but is not limited to, Ti. The electrode 120 may include a metal compound. The electrode 120 may include, for example, but is not limited to, titanium nitride (TiN).

The electrode 140 may be disposed on the nitride semiconductor layer 110. The electrode 140 may contact the second nitride semiconductor layer 110. The electrode 140 may be electrically connected to the nitride semiconductor layer 106. The electrode 140 may be electrically connected to the nitride semiconductor layer 106 through the nitride semiconductor layer 110. A portion of the electrode 140 may be surrounded by the nitride semiconductor layer 110. A portion of the electrode 140 may be surrounded by the dielectric layer 108a. A portion of the electrode 140 may be surrounded by the dielectric layer 108b. The electrode 140 may include a conductive material. The electrode 140 may include a metal. The electrode 140 may include, for example, but is not limited to, Al. The electrode 140 may include, for example, but is not limited to, Ti. The electrode 140 may include a metal compound. The electrode 140 may include, for example, but is not limited to, AlN. The electrode 140 may include, for example, but is not limited to, TiN.

The electrode 130 may be disposed on the nitride semiconductor layer 160. The electrode 130 may be in contact with the nitride semiconductor layer 160. The electrode 130 may be surrounded by the dielectric layer 108b. The electrode 130 may include a metal. The electrode 130 may include, for example, but is not limited to, gold (Au), platinum (Pt), titanium (Ti), palladium (Pd), nickel (Ni), or tungsten (W). The electrode 130 may include a metal compound. The electrode 130 may include, for example, but is not limited to, TiN.

The dielectric layer 108a may improve the surface quality of the surface 116 and the side 118 of the nitride semiconductor layer 110. The dielectric layer 108a may decrease the defects of the surface 116 and the side 118 of the nitride semiconductor layer 110. The dielectric layer 108a may reduce contamination on the surface 116 and the side 118 of the nitride semiconductor layer 110. The dielectric layer 108a may prevent lateral growth of the nitride semiconductor layer 160 on the side 118.

FIG. 3A to FIG. 3H illustrate various stages of a method for manufacturing the semiconductor device 100 as shown in FIG. 2A.

Referring to FIG. 3A, a substrate 102 may be provided. A buffer layer 104 may be formed on the substrate 102. The buffer layer 104 may be formed through chemical vapor deposition (CVD) and/or another suitable deposition step. The buffer layer 104 may be formed on the substrate 102 through CVD and/or another suitable deposition step. A nitride semiconductor layer 106 may be formed on the substrate 102. The nitride semiconductor layer 106 may be formed on the buffer layer 104. The nitride semiconductor layer 106 may be formed through CVD and/or another suitable deposition step. The nitride semiconductor layer 106 may be formed on the substrate 102 or buffer layer 104 through CVD and/or another suitable deposition step. A nitride semiconductor layer 110 may be formed on the nitride semiconductor layer 106. The nitride semiconductor layer 110 may be formed through CVD and/or another suitable deposition step. The nitride semiconductor layer 110 may be formed on the nitride semiconductor layer 106 through CVD and/or another suitable deposition step.

The nitride semiconductor layer 110 may be formed after forming the nitride semiconductor layer 106. A heterojunction may be formed when the nitride semiconductor layer 110 is disposed on the nitride semiconductor layer 106. A band gap of the nitride semiconductor layer 110 may be greater than a band gap of the nitride semiconductor layer 106. Due to the polarization phenomenon of the formed heterojunction between the nitride semiconductor layer 110 and the nitride semiconductor layer 106, 2DEG may be formed in the nitride semiconductor layer 106. Due to the polarization phenomenon of the formed heterojunction between the nitride semiconductor layer 110 and the nitride semiconductor layer 106, 2DEG may be formed in the nitride semiconductor layer 106 and close to an interface between the nitride semiconductor layer 106 and the nitride semiconductor layer 110.

Referring to FIG. 3B, a recess 150 is formed on the nitride semiconductor layer 110 between the surface 112 and the surface 114 of the nitride semiconductor layer 110. The recess may define the side 118 and the surface 116 of the nitride semiconductor layer 110. The bottom wall 152 of the recess defines the surface 116 of nitride semiconductor layer 110. The sidewall 154 of the recess 150 connecting the opening and the bottom wall 152 of the recess defines the side 118 of the nitride semiconductor layer 110. The recess 150 may have a depth Dr. The depth Dr may be defined by the distance between the surface 114 of the nitride semiconductor layer 110 and the surface 116 of the nitride semiconductor layer 110. The depth Dr may equal to the difference between the second height and the third height. The bottom wall 152 of the recess 150 may have a width Wr along the x direction. The depth Dr may range between approximately 500 nm and approximately 3000 nm, preferably between approximately 800 nm and approximately 2500 nm, more preferably between approximately 1000 nm and approximately 2000 nm, and even more preferably between approximately 1200 nm and approximately 1700 nm. The width Wr may range between approximately 2000 nm and approximately 9000 nm, preferably between approximately 3000 nm and approximately 7000 nm, more preferably between approximately 4000 nm and approximately 6000 nm, and even more preferably between approximately 4500 nm and approximately 5500 nm. The recess may be formed by a suitable process, for example, but is not limited to, etching technique (an etching process such as dry etching or wet etching), laser technique (laser drill or laser cutting) or other suitable technique.

Referring to FIG. 3C, a dielectric layer 108a may be formed on the nitride semiconductor layer 110. The dielectric layer 108a may be formed in the recess 150. The dielectric layer 108a covers at least the sidewall 154 of the recess. The dielectric layer 108a covers at least the bottom wall 152 of the recess. The dielectric layer 108a contacts the surface 116. The dielectric layer 108a may also be formed on the surface 114 of the nitride semiconductor layer 110. The dielectric layer 108a contacts the side 118 of the nitride semiconductor layer 110. The dielectric layer 108a may be formed through a deposition step. The dielectric layer 108a may be formed on the nitride semiconductor layer 110 through CVD and/or another suitable deposition step. The dielectric layer 108a may be formed after forming the nitride semiconductor layer 110. The dielectric layer 108a may be formed right after forming the nitride semiconductor layer 110. The dielectric layer 108a may be formed right after forming the nitride semiconductor layer 110 to prevent or suppress oxidation of the nitride semiconductor layer 110. The dielectric layer 108a may prevent or suppress contamination on the sidewall of the recess.

Referring to FIG. 3D, a portion of the dielectric layer 108a on the bottom wall 152 of the recess 150 may be removed to expose the corresponding portion of the surface 116 of the nitride semiconductor layer 110. After removal, the dielectric layer 108a may form a terminal 1084 on the surface 116. The terminal 1084 of the dielectric layer 108a on the surface 116 may be substantially parallel to the z direction. None of the side 118 of the nitride semiconductor layer 110 is exposed after the removal step. The surface 116 of the nitride semiconductor layer 110 is exposed after the removal step. A portion of the dielectric layer 108a on the surface 114 of the nitride semiconductor layer 110 is removed. The removal step may be performed by a suitable process, for example, but is not limited to, etching technique (an etching process such as dry etching or wet etching), laser technique (laser drill or laser cutting) or other suitable technique.

Referring to FIG. 3E, a nitride semiconductor layer 160 may be formed. The nitride semiconductor layer 160 may be formed through a deposition step. The nitride semiconductor layer 160 may be formed on the semiconductor layer 110 through CVD and/or another suitable deposition step. The nitride semiconductor layer 160 may epitaxially formed on the nitride semiconductor layer 110. The nitride semiconductor layer 160 may epitaxially formed on the surface 116. The nitride semiconductor layer 160 may be formed on the dielectric layer 108a through CVD and/or another suitable deposition step. The nitride semiconductor layer 160 may be formed on the surface 114 of the semiconductor layer 110. The nitride semiconductor layer 160 may be formed in the recess 150. The nitride semiconductor layer 160 may be formed on the surface 116 of the semiconductor layer 110. The nitride semiconductor layer 160 may contact the surface 116 of the semiconductor layer 110. The nitride semiconductor layer 160 may be formed on the portion of the surface 116 exposed by the removal step. The dielectric layer 108a is between the nitride semiconductor layer 160 and the nitride semiconductor layer 110. The dielectric layer 108a is between the nitride semiconductor layer 160 and the surface 114, the surface 116, and/or the side 118 of the nitride semiconductor layer 110. The dielectric layer 108a contacts the nitride semiconductor layer 160 and the side 118 of the nitride semiconductor layer 110. The surface of the nitride semiconductor layer 160 facing the surface 116 is defined as the surface 162 of the nitride semiconductor layer 160. The surface 162 of the nitride semiconductor layer 160 has a width w along the x direction. The width w may range between approximately 1000 nm and approximately 9000 nm, preferably between approximately 2000 nm and approximately 7000 nm, more preferably between approximately 3000 nm and approximately 6000 nm, and even more preferably between approximately 4000 nm and approximately 5000 nm. The width w is of about 10% to about 100% of the width Wr, preferably about 50% to about 95%, more preferably about 70% to about 90%.

The lateral surface of the nitride semiconductor layer 160 formed in the recess 150 is defined as the side 166 of the nitride semiconductor layer 160. The side 166 of the nitride semiconductor layer 160 is substantially perpendicular to the surface of the substrate. A portion of the side 166 of the nitride semiconductor layer 160 is defined by the dielectric layer 108a. A portion of the side 166 of the nitride semiconductor layer 160 is not defined by the dielectric layer 108a. A portion of the side 166 of the nitride semiconductor layer 160 may be in contact with the dielectric layer 108a. A portion of the side 166 of the nitride semiconductor layer 160 is in contact with the terminal of the dielectric layer 108a on the surface 116. The terminal is substantially parallel to the z direction. A portion of the side 166 of the nitride semiconductor layer 160 may not be in contact with the dielectric layer 108a.

Referring to FIG. 3F, a portion of the nitride semiconductor layer 160 may be removed. The nitride semiconductor layer 160 may be removed by any suitable process, for example, but is not limited to, etching technique (an etching process such as dry etching or wet etching), laser technique (laser drill or laser cutting) or other suitable technique. A portion of the nitride semiconductor layer 160 on the surface 114 of the nitride semiconductor layer 110 is removed. All the nitride semiconductor layer 160 on the surface 114 of the nitride semiconductor layer 110 are removed. A portion of the nitride semiconductor layer 160 forming in the recess 150 is removed. The top surface of the nitride semiconductor layer 160 in the recess 150 formed by the removal step is defined as the surface 164 of the nitride semiconductor layer 160. The surface 114 of the nitride semiconductor layer 110 is between the surface 162 and the surface 164 of the nitride semiconductor layer 160. A portion of the dielectric layer 108a is removed. A top surface of the dielectric layer 108a is formed by the removal step. The top surface of the dielectric layer 108a formed after the removal step together with the surface 116 of the nitride semiconductor layer 110 define a thickness T of the dielectric layer 108a, thickness T is the distance between the top surface of the dielectric layer 108a and the surface 116 of the nitride semiconductor layer 110. The thickness T may range between approximately 510 nm and approximately 3500 nm, preferably between approximately 800 nm and approximately 3000 nm, more preferably between approximately 1000 nm and approximately 2500 nm, and even more preferably between approximately 1200 nm and approximately 2000 nm.

Referring to FIG. 3G, an electrode 120, an electrode 130 and an electrode 140 may be formed. The electrodes each independently may be formed through physical vapor deposition (PVD), atomic layer deposition (ALD) and/or another suitable deposition step. The electrode 120 and the electrode 140 each independently may be formed on the nitride semiconductor layer 110. The electrode 130 may be formed on the semiconductor layer 160. The electrode 120 and the electrode 140 each independently may be in contact with the dielectric layer 108a. The electrode 120 and the electrode 140 each independently may not be in contact with the dielectric layer 108a.

Referring to FIG. 3H, a dielectric layer 108b may be formed. The dielectric layer 108b may be formed through a deposition step. The dielectric layer 108b may be formed on the nitride semiconductor layer 110 through CVD and/or another suitable deposition step. The dielectric layer 108b may cover at least one of the electrode 120, the electrode 130, the electrode 140, the dielectric layer 108a, the remaining portion of the recess 150, the nitride semiconductor layer 160, and the nitride semiconductor layer 110. The dielectric layer 108b may be in contact with the side 166 of the nitride semiconductor layer 160. The dielectric layer 108b may not be in contact with the side 166 of the nitride semiconductor layer 160.

FIG. 2B is another side view of a semiconductor device according to some embodiments of the disclosure. The semiconductor device shown in FIG. 2B is similar to the semiconductor device 100 shown in FIG. 2A, but differs in the configuration of the dielectric layer 108a and the electrode 120, as well as in the configuration of the nitride semiconductor layer 160 and the nitride semiconductor layer 110. As shown in FIG. 2B, a spacer layer 180 may be formed on the nitride semiconductor layer 110 and may be located between the electrode 120 and the dielectric layer 108a, so that the dielectric layer 108a is not in contact with the electrode 120. In some embodiments, the spacer layer 180 may be formed of the same material as that of the dielectric layer 108b. In some embodiments, a transition layer 182 may be formed between the nitride semiconductor layer 160 and the nitride semiconductor layer 110. The transition layer 182 may be made of aluminum nitride (AlN), Al% grading AlGaN, p-AlGaN, InAlN, InAlGaN, p-GaN.

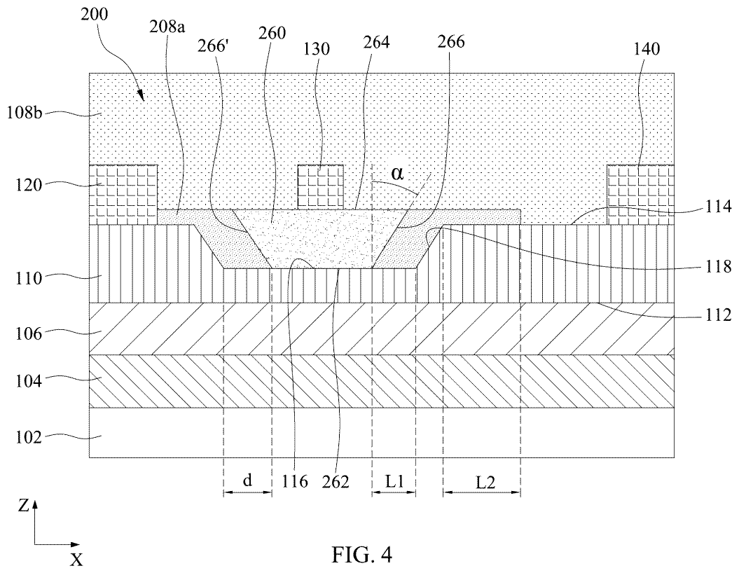

FIG. 4 is a side view of a semiconductor device 200 according to some embodiments of the disclosure.

The semiconductor device 200 shown in FIG. 4 is similar to the semiconductor device 100 shown in FIG. 2A, but differs in the configuration of the dielectric layer 208a and the nitride semiconductor layer 260. The dielectric layer 208a and the nitride semiconductor layer 260 may have a structure different from that as shown in FIG. 2A.

As shown in FIG. 4, the nitride semiconductor layer 260 is surrounded by the dielectric layer 208a. The side 266 of the nitride semiconductor layer 260 extends along the x direction. The projection of the side 266 of the nitride semiconductor layer 260 to the substrate 102 overlaps the projection of the surface 116 of the nitride semiconductor layer 110. The projection of the side 266 of the nitride semiconductor layer 260 to the substrate 102 does not overlap the projection of the surface 262 of the third semiconductor layer 260. The side 266 of the nitride semiconductor layer 260 is inclined at an acute angle α from the z direction. The angle α ranges between about 0° and less than 90°, preferably between 0° and about 70°, more preferably between 10° and about 60°, more preferably between 15° and about 50°, even more preferably between 30° and about 45°. The side 266 of the nitride semiconductor layer 260 may be parallel to the side 118 of the nitride semiconductor layer 110. In another embodiment, the side 266 of the nitride semiconductor layer 260 may not be parallel to the side 118 of the nitride semiconductor layer 110. The nitride semiconductor layer 260 may comprise a side 266′ connecting the surface 262 and surface 264. The arrangement of the side 266′ may be substantially the same as the side 266, except that the side 266 faces the electrode 140, and the side 266′ faces the electrode 120. The dielectric layer 108b does not contact the side 266. The dielectric layer 108b is disposed above the fourth height. The dielectric layer 108b is disposed above the second height.

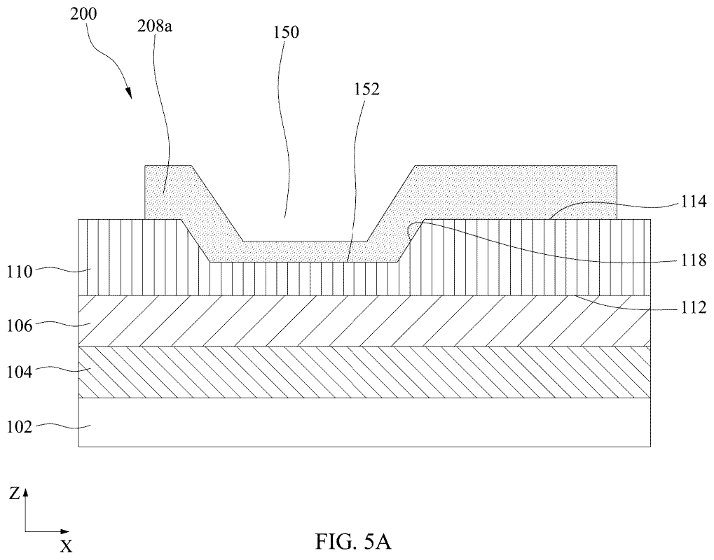

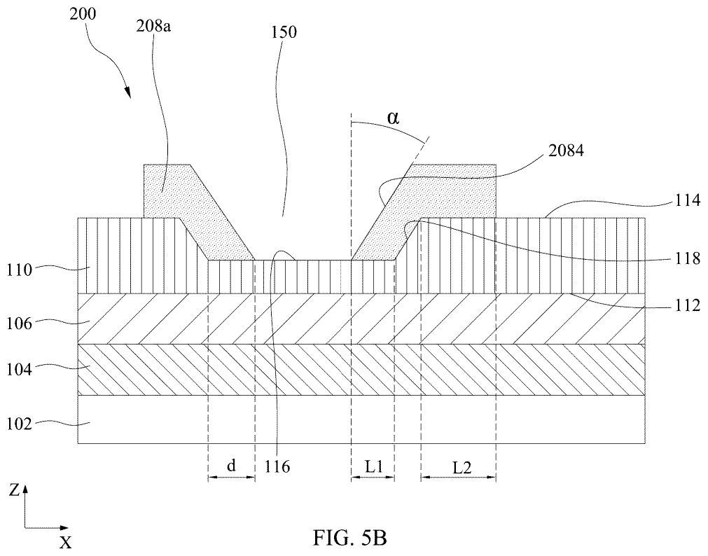

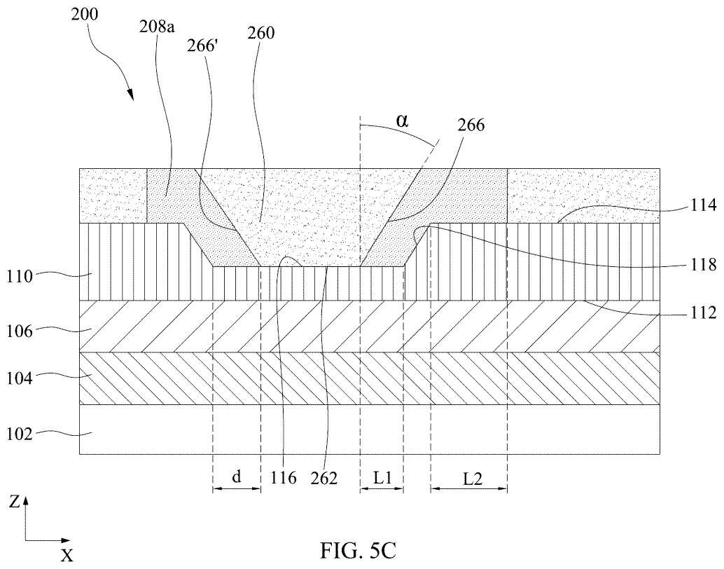

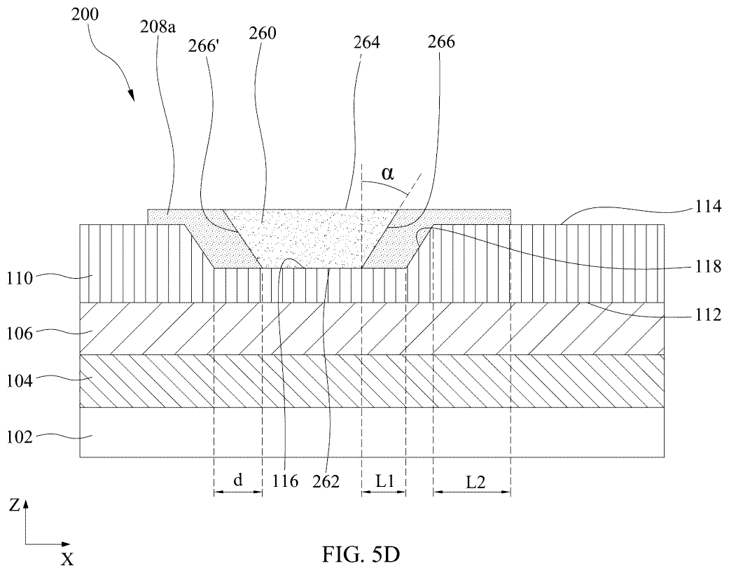

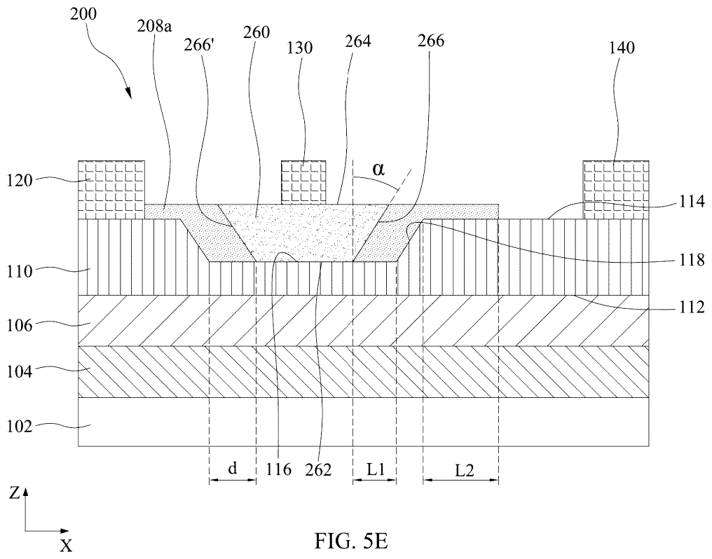

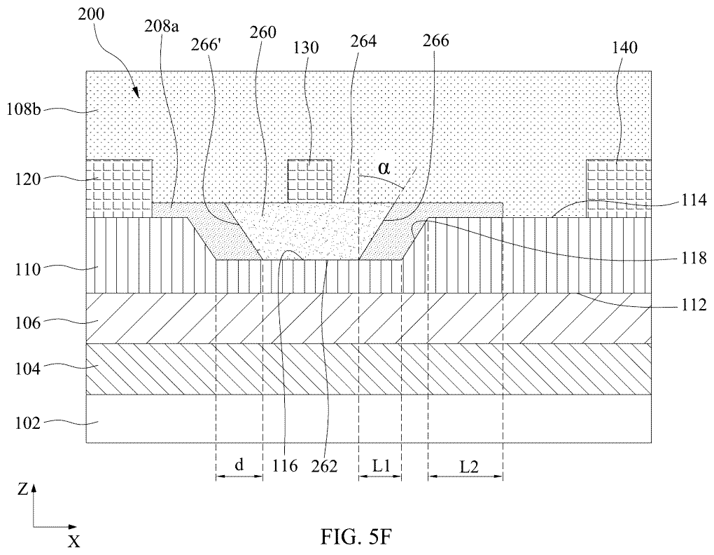

FIG. 5A to FIG. 5F illustrate various stages of a method for manufacturing the semiconductor device 200 as shown in FIG. 4. The manufacture of the semiconductor device 200 may start with the same steps as shown in FIGS. 3A and 3B, then followed by the steps illustrated in FIG. 5A to FIG. 5H.

Referring to FIG. 5A, a dielectric layer 108a may be formed on the second nitride semiconductor layer 110. The first dielectric layer 108a may be formed on the third surface 116 and the first side 118 of the second nitride semiconductor layer 110.

Referring to FIG. 5B, a portion of the dielectric layer 208a on the bottom wall 152 of the recess 150 may be removed to expose the corresponding portion of the surface 116 of the nitride semiconductor layer 110. The step shown in FIG. 5B is similar to the step shown in FIG. 3D. The difference resides in that the dielectric layer 108a of the semiconductor device 100 comprises a terminal on the surface 116 that is substantially parallel to the z direction. In contrast, the dielectric layer 208a forms an inclined surface 2084 in the recess 150, the inclined surface 2084 is at an acute angle α from the z direction. The removal step may be performed by a suitable process, for example, but is not limited to, etching technique (an etching process such as dry etching or wet etching), laser technique (laser drill or laser cutting) or other suitable technique.

Referring to FIG. 5C, a nitride semiconductor layer 260 may be formed. The nitride semiconductor layer 260 may be formed through a deposition step. The dielectric layer 208a surrounds the side 266 of the nitride semiconductor layer 260. The dielectric layer 208a defines the side 266 of the nitride semiconductor layer 260 such that the side 266 is inclined at the same angle as the dielectric layer 208a. The dielectric layer 208a is in contact with the side 266 of the nitride semiconductor layer 260.

Referring to FIG. 5D, a portion of the nitride semiconductor layer 260 may be removed to form the surface 264 of the nitride semiconductor layer 260. A portion of the first dielectric layer 208a may also be removed. A portion of the dielectric layer 208a is removed such that the top surface of the dielectric layer 208a flushes with the surface 264 of the nitride semiconductor layer 260.

Referring to FIG. 5E, an electrode 120, an electrode 130 and an electrode 140 may be formed. The electrodes each independently may be formed through physical vapor deposition (PVD), atomic layer deposition (ALD) and/or another suitable deposition step.

Referring to FIG. 5F, a dielectric layer 108b may be formed. The dielectric layer 108b may be formed through a deposition step. The dielectric layer 108b is not in contact with the side 266 of the nitride semiconductor layer 260.

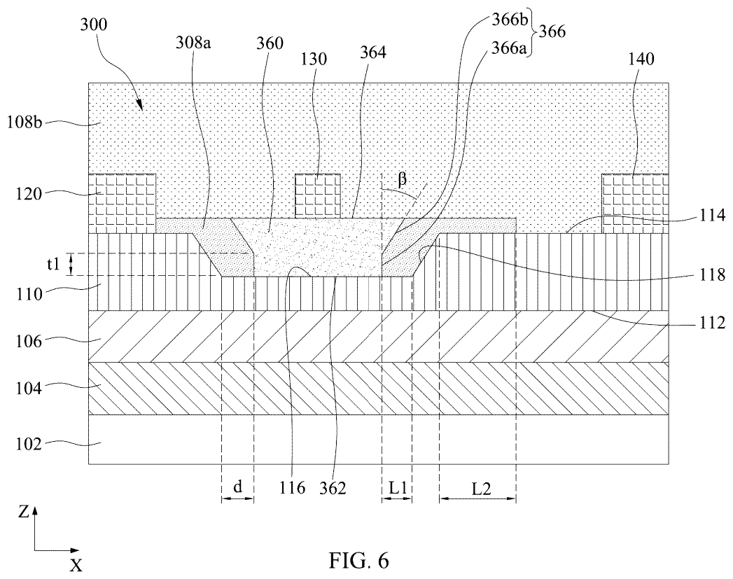

FIG. 6 is a side view of a semiconductor device 300 according to some embodiments of the disclosure.

The semiconductor device 300 shown in FIG. 6 is similar to the semiconductor device 200 shown in FIG. 4, but differs in the configuration of the dielectric layer 308a and the side 366 of the nitride semiconductor layer 360. The side 366 of the nitride semiconductor layer 360 has two different portions 366a and 366b.

As shown in FIG. 6, the side 366 of the nitride semiconductor layer 360 includes a portion 366a extending along the z. The side 366 includes a portion 366b connecting the portion 366a and the surface 364. The portion 366b extends along the x direction. The portion 366a of the side 366 of the nitride semiconductor layer 360 has a thickness t1, which is defined as the projection of the portion 366a of the nitride semiconductor layer 360 to the z direction. The thickness t1 may range between approximately 10 nm and approximately 1500 nm, preferably between approximately 50 nm and approximately 2000 nm, more preferably between approximately 100 nm and approximately 1500 nm, and even more preferably between approximately 300 nm and approximately 700 nm.

The projection of the portion 366b of the nitride semiconductor layer 360 to the substrate 102 overlaps the projection of the surface 116 of the nitride semiconductor layer 110. The projection of the portion 366b of the nitride semiconductor layer 360 to the substrate 102 does not overlap the projection of the side 118 of the nitride semiconductor layer 110. In another embodiment, the projection of the portion 366b of the nitride semiconductor layer 360 to the substrate 102 overlaps the projection of the side 118 of the nitride semiconductor layer 110. The portion 366b of the third nitride semiconductor layer 360 is inclined at an acute angle β from the z direction. The projection of the portion 366b of the nitride semiconductor layer 360 to the z direction overlaps the projection of the side 118 of the nitride semiconductor layer 110. In another embodiment, the projection of the portion 366b of the nitride semiconductor layer 360 to the z direction does not overlap the projection of the side 118 of the nitride semiconductor layer 110. The angle β ranges between about 0° and less than 90°, preferably between 0° and about 70°, more preferably between 10° and about 60°, more preferably between 15° and about 50°, even more preferably between 30° and about 45°.

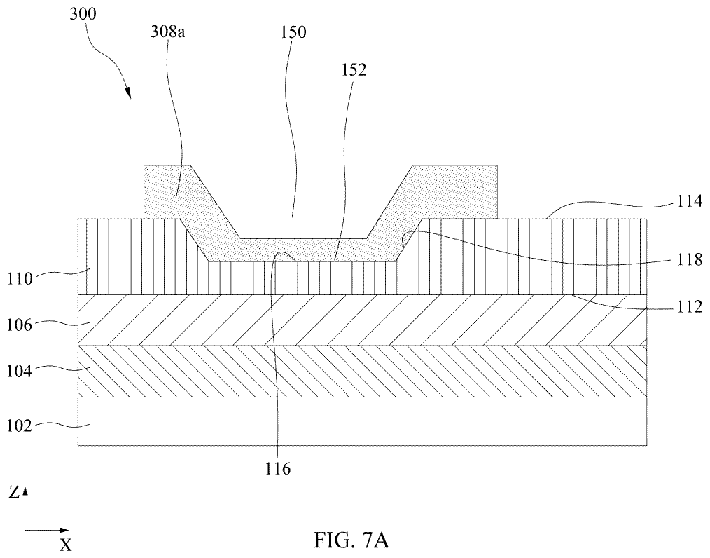

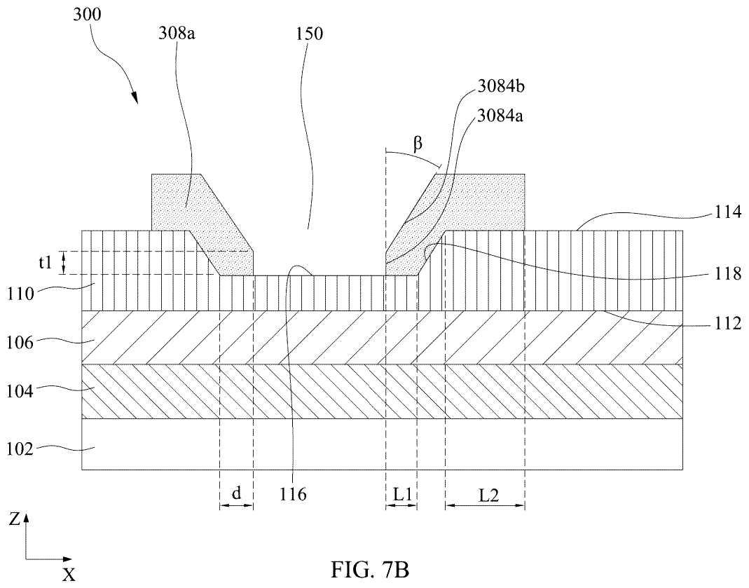

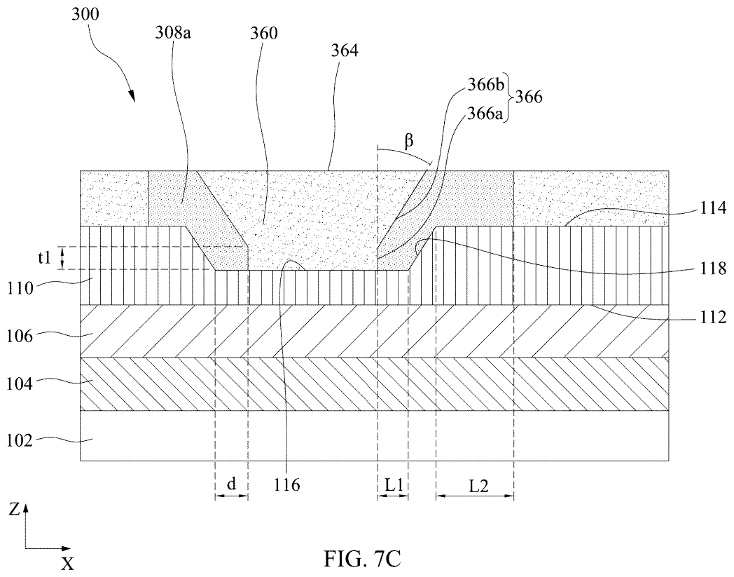

FIG. 7A to FIG. 7C illustrate various stages of a method for manufacturing the semiconductor device 300 as shown in FIG. 6. The manufacture of the semiconductor device 300 may start with the same steps as shown in FIGS. 3A and 3B, then followed by the steps illustrated in FIG. 7A to FIG. 7C and FIG. 5D to FIG. 5F.

Referring to FIG. 7A, a dielectric layer 308a may be formed on the nitride semiconductor layer 110. The dielectric layer 308a may be formed on the surface 116 and the side 118 of the nitride semiconductor layer 110.

Referring to FIG. 7B, a portion of the dielectric layer 308a on the bottom wall 152 of the recess 150 may be removed to expose the corresponding portion of the surface 116 of the nitride semiconductor layer 110. The removal includes perpendicularly etching the portion of the dielectric layer 308a on the surface 116 of the nitride semiconductor layer 110. The step shown in FIG. 7B is similar to the step shown in FIG. 5B. The difference resides in that the dielectric layer 208a of the semiconductor device 200 forms an inclined surface 2084 in the recess 150. The inclined surface 2084 is at an acute angle a from the z direction. In contrast, the dielectric layer 308a comprises a terminal 3084a on the surface 116 and an inclined surface 3084b in the recess 150. The terminal 3084a connects the surface 3084b and the surface 116. The removal step may be performed by a suitable process, for example, but is not limited to, etching technique (an etching process such as dry etching or wet etching), laser technique (laser drill or laser cutting) or other suitable technique.

Referring to FIG. 7C, a nitride semiconductor layer 360 may be formed. The nitride semiconductor layer 360 may be formed through a deposition step. The dielectric layer 308a surrounds the side 366 of the nitride semiconductor layer 360. The dielectric layer 308a defines the side 366 of the nitride semiconductor layer 360 such that the side 366 has a portion 366a extending along the z direction and a portion 366b connecting the portion 366a and the surface 364. The portion 366b extends along the x direction. The dielectric layer 308a is in contact with the side 366 of the nitride semiconductor layer 360.

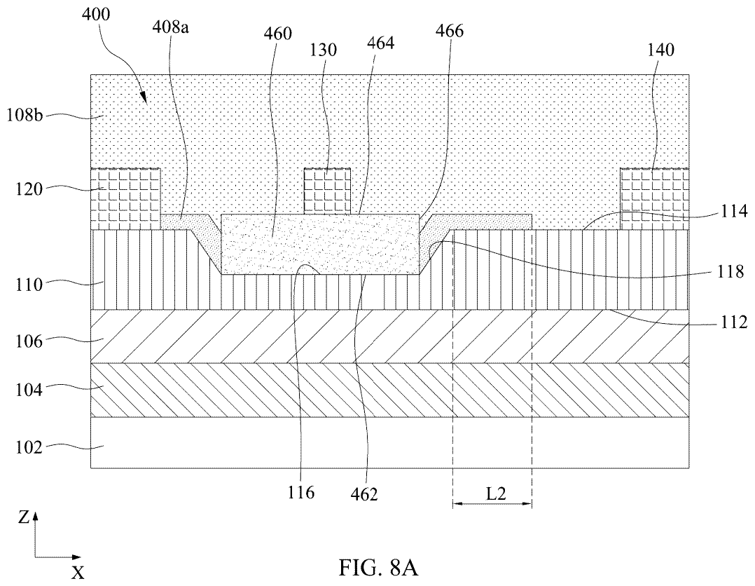

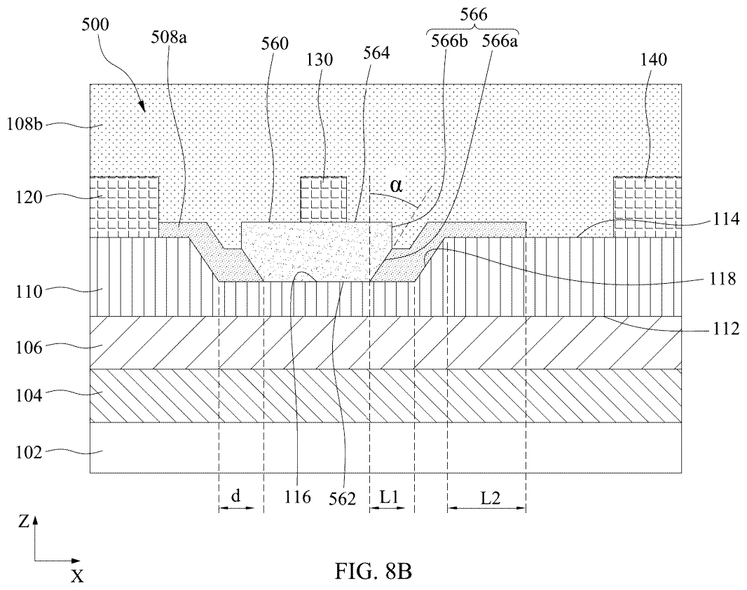

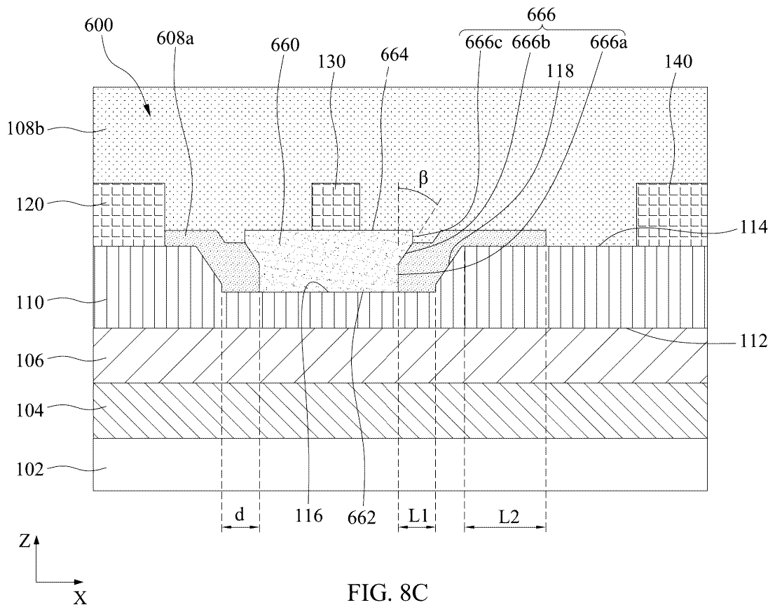

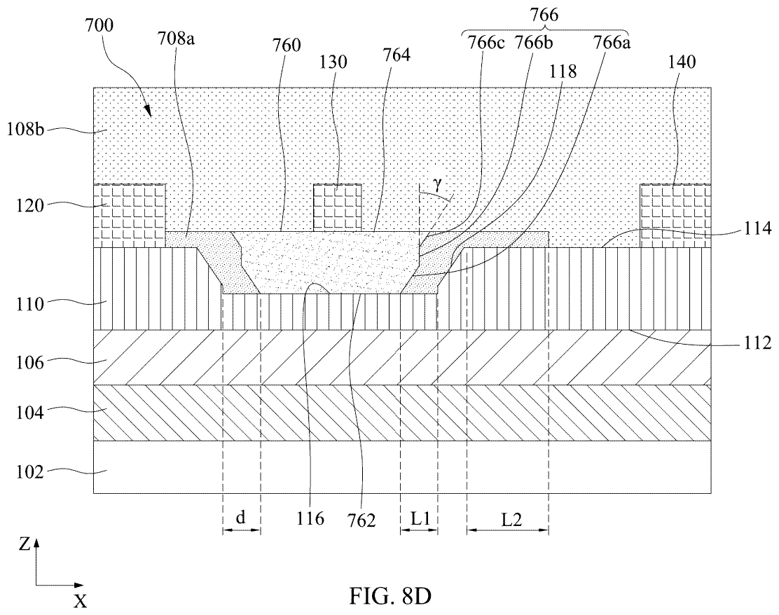

FIG. 8A to FIG. 8D respectively are a side view of semiconductor devices 400, 500, 600, and 700 according to some embodiments of the disclosure. The semiconductor devices shown in FIG. 8A to FIG. 8D are similar to the semiconductor devices 100 and 200 shown in FIG. 2A and FIG. 4, but differs in the configuration of the dielectric layer 408a, 508a, 608a, or 708a and the side 466, 566, 666, or 766 of the nitride semiconductor layer 460, 560, 660, or 760.

As shown in FIG. 8A, the side 466 of the nitride semiconductor layer 460 of the semiconductor device 400 is substantially perpendicular to the surface of the substrate. The projection of the surface 116 to the substrate 102 falls within the projection of the surface 462 to the substrate 102. The projection of the surface 462 to the substrate 102 falls within the projection of the surface 116 to the substrate 102. The nitride semiconductor layer 460 covers the surface 116 of the nitride semiconductor layer 110. The dielectric layer 408a contacts the surface 114 of the nitride semiconductor layer 110. The dielectric layer 408a may extend a length L2 on the surface 114 along the x direction. In another embodiment, the dielectric layer 408a may not contact the surface 114 of the nitride semiconductor layer 110. The dielectric layer 408a does not contact the surface 116 of the nitride semiconductor layer 110. The dielectric layer 408a may be between the second height and the third height. The dielectric layer 408a may be between the fourth height and the third height.

As shown in FIG. 8B, the side 566 of the nitride semiconductor layer 560 of the semiconductor device 500 has portions 566a and 566b. The portion 566a is inclined at an angle a from the z direction. The portion 566b is substantially parallel to the z direction. Portion 566a connects the surface 116 and portion 566b. Portion 566b connects portion 566a and the surface 564. The portion 566a is inclined at an acute angle a from the z direction. The projection of the portion 566a of the nitride semiconductor layer 560 to the substrate 102 overlaps the projection of the surface 116 of the nitride semiconductor layer 110. The projection of the portion 566a of the nitride semiconductor layer 560 to the substrate 102 do not overlaps the projection of the side 118 of the nitride semiconductor layer 110. In another embodiment, the projection of the portion 566a of the nitride semiconductor layer 560 to the substrate 102 overlaps the projection of the side 118 of the nitride semiconductor layer 110. The projection of the portion 566a of the nitride semiconductor layer 560 to the z direction overlaps the projection of the side 118 of the nitride semiconductor layer 110. The projection of the portion 566b of the nitride semiconductor layer 560 to the z direction overlaps the projection of the side 118 of the nitride semiconductor layer 110. In another embodiment, the projection of the portion 566b of the nitride semiconductor layer 560 to the z direction does not overlap the projection of the side 118 of the nitride semiconductor layer 110.

The dielectric layer 508a contacts the surface 114 of the nitride semiconductor layer 110. The dielectric layer 508a may extend a length L2 on the surface 114 along the x direction. In another embodiment, the dielectric layer 508a may not contact the surface 114 of the nitride semiconductor layer 110. The dielectric layer 508a contacts the surface 116 of the nitride semiconductor layer 110. The dielectric layer 508a may extend a length L1 on the surface 116 along the x direction. The dielectric layer 508a contacts the side 118 of the nitride semiconductor layer 110. The dielectric layer 508a contacts the portion 566a of the side 566 of the nitride semiconductor layer 560. The dielectric layer 508a may or may not contact the portion 566b of the side 566 of the nitride semiconductor layer 560. The portion 566a of the side 566 and the side 118 comprise a distance d therebetween on the third height. The dielectric layer 508a may be between the second height and the third height. The dielectric layer 508a may be between the fourth height and the third height.

As shown in FIG. 8C, the side 666 of the nitride semiconductor layer 660 of the semiconductor device 600 includes portions 666a, 666b, 666c. The portion 666a extends along the z direction. The portion 666c extends along the z direction. The portion 666b is inclined at an angle β from the z direction. The 666a connects the surface 116 and portion 666b. The portion 666b connects the portion 666a and the portion 666c. The portion 666c connects the portion 666b and the surface 664. The projection of the portion 666b of the nitride semiconductor layer 660 to the substrate 102 overlaps the projection of the surface 116 of the nitride semiconductor layer 110. The projection of the portion 666b of the nitride semiconductor layer 660 to the substrate 102 does not overlap the projection of the side 118 of the nitride semiconductor layer 110. In another embodiment, the projection of the portion 666b of the nitride semiconductor layer 660 to the substrate 102 overlaps the projection of the side 118 of the nitride semiconductor layer 110. The projection of the portion 666b of the nitride semiconductor layer 660 to the z direction overlaps the projection of the side 118 of the nitride semiconductor layer 110. In another embodiment, the projection of the portion 666b of the nitride semiconductor layer 660 to the z direction does not overlap the projection of the side 118 of the nitride semiconductor layer 110. The projection of the portion 666c of the nitride semiconductor layer 660 to the z direction overlaps the projection of the side 118 of the nitride semiconductor layer 110. In another embodiment, the projection of the portion 666c of the nitride semiconductor layer 660 to the z direction does not overlap the projection of the side 118 of the nitride semiconductor layer 110.

The dielectric layer 608a contacts the surface 114 of the nitride semiconductor layer 110. The dielectric layer 608a may extend a length L2 on the surface 114 along the x direction. In another embodiment, the dielectric layer 608a may not contact the surface 114 of the nitride semiconductor layer 110. The dielectric layer 608a contacts the surface 116 of the nitride semiconductor layer 110. The dielectric layer 608a may extend a length L1 on the surface 116 along the x direction. The dielectric layer 608a contacts the side 118 of the nitride semiconductor layer 110. The dielectric layer 608a contacts the portion 666a of the nitride semiconductor layer 660. The dielectric layer 608a contact the portion 666b of the nitride semiconductor layer 660. In another embodiment, the dielectric layer 608a may not contact the portion 666b of the nitride semiconductor layer 660. The dielectric layer 608a does not contact the portion 666c of the nitride semiconductor layer 660. In another embodiment, the dielectric layer 608a may contact the portion 666c of the nitride semiconductor layer 660. The portion 666a of the side 666 and the side 118 comprise a distance d therebetween on the third height. The dielectric layer 608a may be between the portion 666b and the surface 116. The dielectric layer 608a may be between the second height and the third height. The dielectric layer 608a may be between the fourth height and the third height.

As shown in FIG. 8D, the side 766 of the nitride semiconductor layer 760 of the semiconductor device 700 includes portions 766a, 766b, 766c. The portion 766a is inclined at an angle α from the z direction. The portion 766b extends along the z direction. The portion 766c is inclined at an angle γ from the z direction. The 766a connects the surface 116 and portion 766b. The portion 766b connects the portion 766a and the portion 766c. The portion 766c connects the portion 766b and the surface 764. The projection of the portion 766a of the nitride semiconductor layer 760 to the substrate 102 overlaps the projection of the surface 116 of the nitride semiconductor layer 110. The portion 766c of the nitride semiconductor layer 760 to the substrate 102 overlaps the projection of the surface 116 of the nitride semiconductor layer 110. In another embodiment, the projection of the portion 766c of the nitride semiconductor layer 760 to the substrate 102 does not overlap the projection of the surface 116 of the nitride semiconductor layer 110. In another embodiment, the projection of the portion 766c of the nitride semiconductor layer 760 to the substrate 102 may overlap the projection of the surface 114 of the nitride semiconductor layer 110. The projection of the portion 766a of the nitride semiconductor layer 760 to the substrate 102 overlaps the projection of the side 118 of the nitride semiconductor layer 110. The projection of the portion 766c of the nitride semiconductor layer 760 to the substrate 102 overlaps the projection of the side 118 of the nitride semiconductor layer 110. In another embodiment, the projection of the portion 766c of the nitride semiconductor layer 760 to the substrate 102 does not overlap the projection of the first side 118 of the second nitride semiconductor layer 110. The projection of the portion 766a of the nitride semiconductor layer 760 to the z direction overlaps the projection of the side 118 of the nitride semiconductor layer 110. The projection of the portion 766b of the nitride semiconductor layer 760 to the z direction overlaps the projection of the side 118 of the nitride semiconductor layer 110. The projection of the portion 766c of the nitride semiconductor layer 760 to the z direction overlaps the projection of the side 118 of the nitride semiconductor layer 110. In another embodiment, the projection of the portion 766b of the nitride semiconductor layer 760 to the z direction does not overlap the projection of the side 118 of the nitride semiconductor layer 110. In another embodiment, the projection of the portion 766c of the nitride semiconductor layer 760 to the z direction does not overlap the projection of the side 118 of the nitride semiconductor layer 110. The angle γ ranges between about 0° and about 90°, preferably between 0° and about 70°, more preferably between 10° and about 60°, more preferably between 15° and about 50°, even more preferably between 30° and about 45 °.

The dielectric layer 708a contacts the surface 114 of the nitride semiconductor layer 110. The dielectric layer 708a may extend a length L2 on the surface 114 along the x direction. In another embodiment, the dielectric layer 708a may not contact the surface 114 of the nitride semiconductor layer 110. The dielectric layer 708a contacts the surface 116 of the nitride semiconductor layer 110. The dielectric layer 708a may extend a length L1 on the surface 116 along the x direction. The dielectric layer 708a contacts the side 118 of the nitride semiconductor layer 110. The dielectric layer 708a contacts the portion 766a of the nitride semiconductor layer 760. The dielectric layer 708a contact the portion 766b of the nitride semiconductor layer 760. In another embodiment, the dielectric layer 708a may not contact the portion 766b of the nitride semiconductor layer 760. The dielectric layer 708a contact the portion 766c of the nitride semiconductor layer 760. In another embodiment, the dielectric layer 708a may not contact the portion 766c of the nitride semiconductor layer 760. The portion 766a of the side 766 and the side 118 comprise a distance d therebetween on the third height. The dielectric layer 708a may be between the portion 766a and the surface 116. The dielectric layer 708a may be between the portion 766c and the surface 116. In another embodiment, the dielectric layer 708a may be between the portion 766c and the surface 114. The dielectric layer 608a may be between the second height and the third height. The dielectric layer 608a may be between the fourth height and the third height.

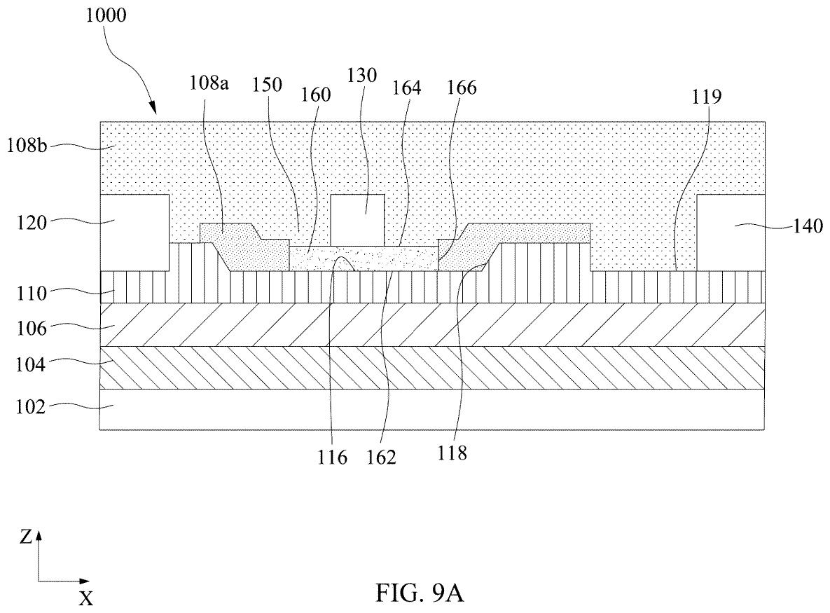

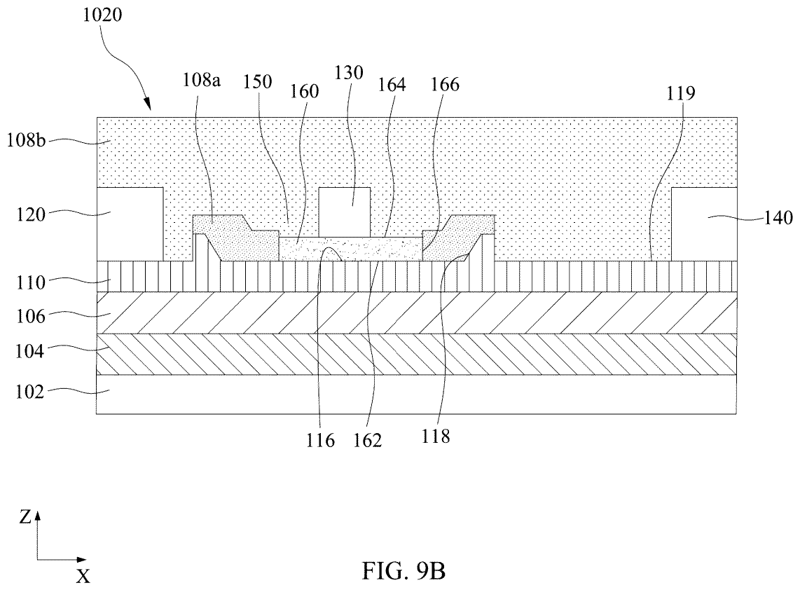

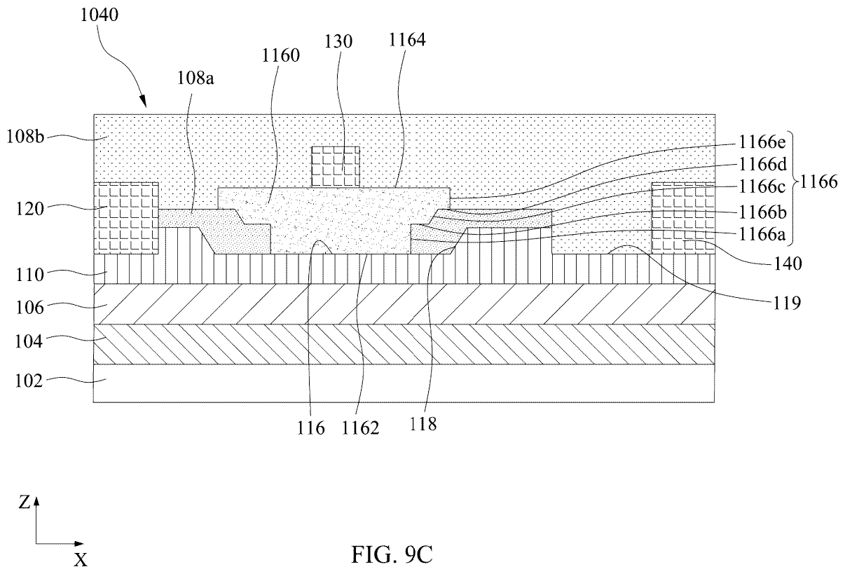

FIG. 9A to FIG. 9C respectively are a side view of semiconductor devices 1000, 1020, and 1040 according to some embodiments of the disclosure. The semiconductor devices 1000, 1020, and 1040 shown in FIG. 9A to FIG. 9C may have a structure similar to the structure of the semiconductor device 100 shown in FIG. 2A. The differences are described below.

As shown in FIG. 9A to FIG. 9C, the nitride semiconductor layer 110 includes a surface 119 at a fifth height. The fifth height may be greater than the first height. The fifth height may be less than the second height. The fifth height may be greater than the third height. The fifth height may be less than the third height. The fifth height may be greater than the fourth height. The fifth height may be less than the fourth height. The surface 119 may be formed by removal of a portion of the nitride semiconductor layer 110. The removal step may be performed by a suitable process, for example, but is not limited to, etching technique (an etching process such as dry etching or wet etching), laser technique (laser drill or laser cutting) or other suitable technique. The surface 119 of the nitride semiconductor layer 110 may be between the surface 112 and the surface 116 of the nitride semiconductor layer 110. The surface 119 of the nitride semiconductor layer 110 may be between the surface 114 and the surface 116 of the nitride semiconductor layer 110. The surface 119 of the nitride semiconductor layer 110 may flush with the surface 116 of the nitride semiconductor layer 110. In the z direction, the surface 119 may be between the top and bottom surfaces of the electrode 120. In the z direction, the surface 119 may be between the top and bottom surfaces of the electrode 140. In the z direction, the surface 119 may be between the surface 114 and the bottom surface of the electrode 120. In the z direction, the surface 119 may be between the surface 114 and the bottom surface of the electrode 140. In the z direction, the surface 119 may be below the bottom surface of the electrode 120. In the z direction, the surface 119 may be below the bottom surface of the electrode 140. Comparing to the surface 119, the bottom surface of the electrode 120 is away from the substrate 102. Comparing to the surface 119, the bottom surface of the electrode 140 is away from the substrate 102. The surface 119 may flush with the bottom surface of the electrode 120. The surface 119 may flush with the bottom surface of the electrode 140.

As shown in FIG. 9C to FIG. 9C, the semiconductor devices may comprise an electrode 120 and an electrode 140 disposed on the surface 119 of the nitride semiconductor layer 110. However, other embodiments may also be applied. For example, the electrode 120 may be disposed on the surface 114 of the nitride semiconductor layer 110 and the electrode 140 may be disposed on the surface 119 of the nitride semiconductor layer 110, and vice versa. The electrode 120 and the electrode 140 each independently may contact at least one of the nitride semiconductor layer 110, the dielectric layer 108a, and the dielectric layer 108b. The electrode 120 and the electrode 140 each independently may be surrounded by at least one of the nitride semiconductor layer 110, the dielectric layer 108a, and the dielectric layer 108b. The electrode 120 and the electrode 140 each independently may not be in contact with the dielectric layer 108a. The lateral surface of the electrode 120 and the electrode 140 each independently may not be in contact with the nitride semiconductor layer 110 or the dielectric layer 108a.

As shown in FIG. 9A and 9B, the surface 164 of the nitride semiconductor layer 160 of the semiconductor device 1000 is between the surface 114 and the surface 116 of the nitride semiconductor layer 110. The side 166 of the nitride semiconductor layer 160 is substantially perpendicular to the surface of the substrate. The dielectric layer 108a contacts the surface 116 of the nitride semiconductor layer 110. The nitride semiconductor layer 160 covers a portion of the surface 116 of the nitride semiconductor layer 110. The nitride semiconductor layer 160 covers the surface 116 of the nitride semiconductor layer 110 at least in the x direction. The dielectric layer 108a contact the surface 114 of the nitride semiconductor layer 110. The dielectric layer 108a covers the surface 114 of the nitride semiconductor layer 110. The dielectric layer 108a covers the surface 114 of the nitride semiconductor layer 110 at least in the x direction. The dielectric layer 108a contacts the side 118 of the nitride semiconductor layer 110. The dielectric layer 108a contacts the side 166 of the nitride semiconductor layer 160. The dielectric layer 108a surrounds the side 166 of the nitride semiconductor layer 160. The dielectric layer 108a may be between the second height and the third height. The dielectric layer 108a may be between the second height and the fourth height. The dielectric layer 108a may be between the second height and the fifth height. The dielectric layer 108a may be between the third height and the fourth height. The dielectric layer 108a may be between the third height and the fifth height. The dielectric layer 108a may not be between the third height and the fifth height. The dielectric layer 108a may be between the fourth height and the fifth height.

As shown in FIG. 9C, the side 1166 of the nitride semiconductor layer 1160 of the semiconductor device 1040 includes portions 1166a, 1166b, 1166c, 1166d, and 1166e. The portion 1166a extends along the z direction. The portion 1166b extends along the x direction. The portion 1166c is inclined at an angle γ from the z direction. The portion 1166d is substantially parallel to the surface of the substrate 102. The portion 1166e extends along the z direction. The 1166a connects the surface 116 and portion 1166b. The portion 1166b connects the portion 1166a and the portion 1166c. The portion 1166c connects the portion 1166b and the portion 116d. The portion 1166d connects the portion 1166c and the portion 116e. The portion 1166e connects the portion 1166d and the surface 1164.

The projection of the portion 1166b of the nitride semiconductor layer 1160 to the surface of the substrate 102 overlaps the projection of the surface 116 of the nitride semiconductor layer 110. The projection of the portion 1166b of the nitride semiconductor layer 1160 to the surface of the substrate 102 does not overlap the projection of the side 118 of the nitride semiconductor layer 110. In another embodiment, the portion 1166b of the nitride semiconductor layer 1160 to the surface of the substrate 102 may overlap the projection of the side 118 of the nitride semiconductor layer 110. The projection of the portion 1166b of the nitride semiconductor layer 1160 to the surface of the substrate 102 does not overlap the projection of the surface 114 of the nitride semiconductor layer 110. In another embodiment, the portion 1166b of the nitride semiconductor layer 1160 to the surface of the substrate 102 may overlap the projection of the surface 114 of the nitride semiconductor layer 110. The projection of the portion 1166c of the nitride semiconductor layer 1160 to the surface of the substrate 102 overlaps the projection of the surface 116 of the nitride semiconductor layer 110. The projection of the portion 1166c of the nitride semiconductor layer 1160 to the surface of the substrate 102 does not overlap the projection of the side 118 of the nitride semiconductor layer 110. In another embodiment, the projection of the portion 1166c of the nitride semiconductor layer 1160 to the surface of the substrate 102 may overlap the projection of the side 118 of the nitride semiconductor layer 110. The projection of the third portion 1166c of the nitride semiconductor layer 1160 to the surface of the substrate 102 does not overlap the projection of the surface 114 of the nitride semiconductor layer 110. In another embodiment, the portion 1166c of the nitride semiconductor layer 1160 to the surface of the substrate 102 may overlap the projection of the surface 114 of the nitride semiconductor layer 110. The projection of the third portion 1166d of the nitride semiconductor layer 1160 to the surface of the substrate 102 overlaps the projection of the surface 116 of the nitride semiconductor layer 110. The projection of the third portion 1166d of the nitride semiconductor layer 1160 to the surface of the substrate 102 does not overlap the projection of the side 118 of the nitride semiconductor layer 110. In another embodiment, the portion 1166d of the nitride semiconductor layer 1160 to the surface of the substrate 102 may overlap the projection of the side 118 of the nitride semiconductor layer 110. The projection of the third portion 1166d of the nitride semiconductor layer 1160 to the surface of the substrate 102 does not overlap the projection of the surface 114 of the nitride semiconductor layer 110. In another embodiment, the portion 1166d of the nitride semiconductor layer 1160 to the surface of the substrate 102 may overlap the projection of the surface 114 of the nitride semiconductor layer 110. The projection of the portion 1166a of the nitride semiconductor layer 1160 to the z direction overlaps the projection of the side 118 of the nitride semiconductor layer 110. However, in yet another embodiment, the projection of the portion 1166a of the nitride semiconductor layer 160 to the z direction may not overlap the projection of the side 118 of the nitride semiconductor layer 110. The projection of the portion 1166c of the nitride semiconductor layer 1160 to the z direction overlaps the projection of the side 118 of the nitride semiconductor layer 110. However, in yet another embodiment, the projection of the portion 1166c of the nitride semiconductor layer 160 to the z direction may not overlap the projection of the side 118 of the nitride semiconductor layer 110. The projection of the portion 1166e of the nitride semiconductor layer 1160 to the z direction does not overlap the projection of the side 118 of the nitride semiconductor layer 110. However, in yet another embodiment, the projection of the portion 1166e of the nitride semiconductor layer 160 to the z direction may overlap the projection of the side 118 of the nitride semiconductor layer 110.

The dielectric layer 108a contacts the surface 116 of the nitride semiconductor layer 110. The dielectric layer 108a covers the surface 116 of the nitride semiconductor layer 110. The dielectric layer 108a covers the surface 116 of the nitride semiconductor layer 110 at least in the x direction. The dielectric layer 108a contacts the surface 114 of the nitride semiconductor layer 110. The dielectric layer 108a covers the surface 114 of the nitride semiconductor layer 110. The dielectric layer 108a covers the surface 114 of the nitride semiconductor layer 110 at least in the x direction. The dielectric layer 108a contacts the side 118 of the nitride semiconductor layer 110. The dielectric layer 108a contacts the portion 1166a of the nitride semiconductor layer 1160. The dielectric layer 108a surrounds the portion 1166a of the nitride semiconductor layer 160. The dielectric layer 108a contacts the portion 1166b of the nitride semiconductor layer 1160. The dielectric layer 108a surrounds the portion 1166b of the nitride semiconductor layer 160. The dielectric layer 108a contacts the portion 1166c of the nitride semiconductor layer 1160. The dielectric layer 108a surrounds the portion 1166c of the nitride semiconductor layer 160. The dielectric layer 108a contacts the portion 1166d of the nitride semiconductor layer 1160. The dielectric layer 108a surrounds the portion 1166d of the nitride semiconductor layer 160. The dielectric layer 108a does not contact the portion 1166e of the nitride semiconductor layer 1160. In another embodiment, the dielectric layer 108a may contact the portion 1166e of the nitride semiconductor layer 1160. In another embodiment, the dielectric layer 108a may surround the portion 1166e of the nitride semiconductor layer 1160. In another embodiment, the dielectric layer 108a may not contact the portion 1166b of the nitride semiconductor layer 1160. In another embodiment, the dielectric layer 108a may not contact the portion 1166c of the nitride semiconductor layer 1160. In another embodiment, the dielectric layer 108a may not contact the portion 1166d of the nitride semiconductor layer 1160. The dielectric layer 108a may be between the portion 1166b and the surface 116. The dielectric layer 108a may be between the portion 1166d and the surface 116. In another embodiment, the dielectric layer 108a may be between the portion 1166b and the surface 114. In another embodiment, the dielectric layer 108a may be between the portion 1166d and the surface 114. The dielectric layer 108a may be between the second height and the third height. The dielectric layer 108a may be between the second height and the fourth height. The dielectric layer 108a may be between the second height and the fifth height. The dielectric layer 108a may be between the third height and the fourth height. The dielectric layer 108a may be between the third height and the fifth height. The dielectric layer 108a may not be between the third height and the fifth height. The dielectric layer 108a may be between the fourth height and the fifth height.

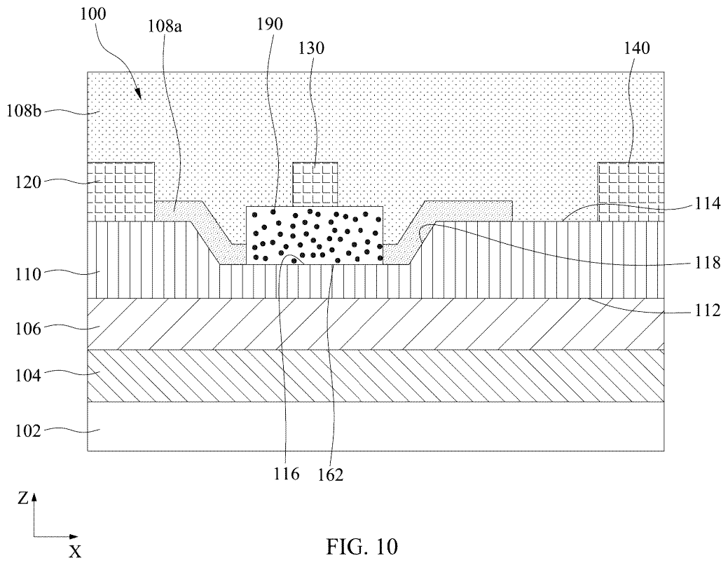

FIG. 10 shows a schematic diagram illustrating the distribution of dopants 190 in the nitride semiconductor layer 160 of the device 100. Without binding to the theory, the dopants 190 (expressed as dots) are evenly distributed. The nitride semiconductor layer 160 shows improved depletion ability. Similar results are applied to the nitride semiconductor layer 260 of device 200, the nitride semiconductor layer 360 of device 300, the nitride semiconductor layer 460 of device 400, the nitride semiconductor layer 560 of device 500, the nitride semiconductor layer 660 of device 600, the nitride semiconductor layer 760 of device 700, the nitride semiconductor layer 160 of device 1000, the nitride semiconductor layer 160 of device 1020, and the nitride semiconductor layer 1160 of device 1040.

As used herein, for ease of description, space-related terms such as “under”, “below”, “lower portion”, “above”, “upper portion”, “lower portion”, “left side”, “right side”, and the like may be used herein to describe a relationship between one component or feature and another component or feature as shown in the figures. In addition to orientations shown in the figures, space-related terms are intended to encompass different orientations of the device in use or operation. A device may be oriented in other ways (rotated 90 degrees or at other orientations), and the space-related descriptors used herein may also be used for explanation accordingly. It should be understood that when a component is “connected” or “coupled” to another component, the component may be directly connected to or coupled to another component, or an intermediate component may exist.

As used herein, terms “approximately”, “basically”, “substantially”, and “about” are used for describing and considering a small variation. When being used in combination with an event or circumstance, the term may refer to a case in which the event or circumstance occurs precisely, and a case in which the event or circumstance occurs approximately. As used herein with respect to a given value or range, the term “about” generally means in the range of ±10%, ±5%, ±1%, or ±0.5% of the given value or range. The range may be indicated herein as from one endpoint to another endpoint or between two endpoints. Unless otherwise specified, all the ranges disclosed in the disclosure include endpoints. The term “substantially coplanar” may refer to two surfaces within a few micrometers (μm) positioned along the same plane, for example, within 10 μm, within 5 μm, within 1 μm, or within 0.5 μm located along the same plane. When reference is made to “substantially” the same numerical value or characteristic, the term may refer to a value within ±10%, ±5%, ±1%, or ±0.5% of the average of the values.

Several embodiments of the disclosure and features of details are briefly described above. The embodiments described in the disclosure may be easily used as a basis for designing or modifying other processes and structures for realizing the same or similar objectives and/or obtaining the same or similar advantages introduced in the embodiments of the disclosure. Such equivalent constructions do not depart from the spirit and scope of the disclosure, and various variations, replacements, and modifications can be made without departing from the spirit and scope of the disclosure.

1. A semiconductor device, comprising:
a substrate;
a first nitride semiconductor layer on the substrate;
a second nitride semiconductor layer on the first nitride semiconductor layer, the second nitride semiconductor layer comprising a first surface at a first height, a second surface at a second height, a third surface at a third height and between the first surface and the second surface, and a first side connecting the second surface and third surface and extending along a direction substantially parallel to the surface of the substrate;
a third nitride semiconductor layer on the third surface of the second nitride semiconductor layer; and
a dielectric layer contacting the third nitride semiconductor layer and the first side of the second nitride semiconductor layer.

2. The semiconductor device according to claim 1, wherein the dielectric layer contacts the third surface of the second nitride semiconductor layer.

3. The semiconductor device according to claim 1, wherein the third nitride semiconductor layer comprises a fourth surface at the third height and a fifth surface at the fourth height; wherein the fourth height is higher than the second height.

4. (canceled)

5. The semiconductor device according to claim 3, wherein the third nitride semiconductor layer comprises a second side connecting the fourth surface and fifth surface of the third nitride semiconductor layer, and the dielectric layer contacts the second side of the third nitride semiconductor layer.

6. The semiconductor device according to claim 5, wherein the second side extends along a direction substantially parallel to the surface of the substrate.

7. The semiconductor device according to claim 6, wherein the projection of the second side of the third nitride semiconductor layer to the substrate non-overlaps the projection of the fourth surface of the third nitride semiconductor layer to the substrate; or,
wherein the projection of the second side of the third nitride semiconductor layer to the substrate overlaps the projection of the fifth surface of the third nitride semiconductor layer to the substrate.

8. (canceled)

9. The semiconductor device according to claim 5, wherein the second side comprises a first portion substantially perpendicular to the surface of the substrate and a second portion extending along a direction substantially parallel to the surface of the substrate.

10. The semiconductor device according to claim 9, wherein the projection of the second portion to the substrate non-overlaps the projection of the fourth surface of the third nitride semiconductor layer to the substrate.

11. The semiconductor device according to claim 9, wherein the projection of the second portion to the substrate overlaps the projection of the fifth surface of the third nitride semiconductor layer to the substrate.

12. The semiconductor device according to claim 9, wherein the second side further comprises a third portion substantially perpendicular to the surface of the substrate, wherein the second portion is between the first portion and the third portion.

13. The semiconductor device according to claim 3, wherein the projection of the fifth surface of the third nitride semiconductor layer to the substrate overlaps the projection of the second surface of the second nitride semiconductor layer.

14. The semiconductor device according to claim 3, wherein the projection of the fifth surface of the third nitride semiconductor layer to the substrate overlaps the projection of the first side of the second nitride semiconductor layer.

15. The semiconductor device according to claim 3, wherein the projection of the second side of the third nitride semiconductor layer to the substrate overlaps the projection of the first side of the second nitride semiconductor layer.

16. A method for fabricating a semiconductor device, comprising:
providing a substrate;
forming a first nitride semiconductor layer on the substrate;
forming a second nitride semiconductor layer on the first nitride semiconductor layer, wherein the second nitride semiconductor layer comprises a first surface at a first height and a second surface at a second height;
etching the second surface of the second nitride semiconductor layer to form a third surface at a third height and between the first surface and the second surface, and a first side connecting the second surface and third surface, wherein the first side extends along a direction substantially parallel to the surface of the substrate;
forming a dielectric layer on the second nitride semiconductor layer;
exposing a portion of the third surface of the second nitride semiconductor layer; and
forming a third nitride semiconductor layer on the third surface of the second nitride semiconductor layer,
wherein the dielectric layer contacts the third nitride semiconductor layer and the first side of the second nitride semiconductor layer.

17. The method according to claim 16, wherein the dielectric layer contacts the third surface of the second nitride semiconductor layer; or,
wherein the third nitride semiconductor layer comprises a fourth surface at the third height and a fifth surface at a fourth height;
wherein the fourth height is higher than the second height.

18. (canceled)

19. (canceled)

20. The method according to claim 16, further comprising removing a portion of the second nitride semiconductor layer to form a sixth surface of the second nitride semiconductor layer, wherein the sixth surface is at a fifth height that is higher than the first height.

21. A semiconductor device, comprising:
a substrate;
a first nitride semiconductor layer on the substrate;
a second nitride semiconductor layer having a first surface at a first height, a second surface at a second height, a third surface at a third height and between the first surface and second surface, and a first side connecting the second surface and the second surface, wherein the first side extends along a direction substantially parallel to the surface of the substrate,
a third nitride semiconductor layer having a fourth surface at the third height, a fifth surface at the fourth height, and a second side connecting the fourth surface and fifth surface, wherein the second side comprises a portion substantially perpendicular to the surface of the substrate.

22. The semiconductor device according to claim 21, wherein the projection of the portion of the second side to the normal of the substrate overlaps the projection of the first side of the second nitride semiconductor to the normal of the substrate; or,
wherein the fourth height is higher than the second height.

23. (canceled)

24. The semiconductor device according to claim 21, further comprises a dielectric between the fifth surface of the third nitride semiconductor layer and the third surface of the second nitride semiconductor layer.

25. The semiconductor device according to claim 21, further comprises a dielectric between the first side of the second nitride semiconductor layer and the second side of the third nitride semiconductor layer.
